(19) United States
(12) Patent Application Publication
(10) Pub. No.: US 2017/0053879 A1
(43) Pub. Date: Feb. 23, 2017

(54) METHOD, A SEMICONDUCTOR DEVICE AND A LAYER ARRANGEMENT

(71) Applicant: Infineon Technologies AG, Neubiberg (DE)

(72) Inventors: SRINIVASA REDDY YEDURU, Villach (AT); RAINER PELZER, Wernberg (AT); STEFAN WOEHLERT, Villach (AT)

(21) Appl. No.: 14/831,937

(22) Filed: Aug. 21, 2015

(51) Int. Cl. H01L 23/00

(52) U.S. Cl. CPC H01L 24/05; H01L 24/08; H01L 2924/01013; H01L 2924/01029; H01L 2924/01047; H01L 2924/01079; H01L 2924/014; H01L 2224/0239

(57) ABSTRACT

A semiconductor device may include: a substrate; a metallization layer disposed at least one of in or over the substrate; a protection layer disposed at least partially over the metallization layer, wherein the metallization layer includes at least one of: copper, aluminum, gold, silver; and wherein the protection layer includes a nitride material including at least one of: copper, aluminum, gold, silver.

### TECHNICAL FIELD

Various embodiments relate generally to a method, a semiconductor device and a layer arrangement.

### BACKGROUND

In general, a metallic surface may chemically interact when exposed to environmental influences. For example, the metallic surface may oxidize, absorb organic substances and/or humidify. The chemical interaction may alter the physical properties like adhesion capability and/or electrical conductivity. This complicates several fabrication steps like electrical contacting the metallic surface and requires additional effort to reverse or avoid the alteration the physical properties.

For metallization layers (e.g. Cu layers), chemical interactions like the formation of oxides (e.g. CuO or CuO₂) is a challenging concern. In the case of contact pads, the formation of oxides causes pad discolorations and non-stick on pad (NSOP) failures (e.g. bonding irregularities, insufficient wire bond adhesion). Oxide layers in the metallic interfaces (e.g. Cu to Cu interconnects) may impair etching the interface, weakening adhesion of wire bonds and also impair the electrical conductivity of the interface.

Conventionally, artificial oxide protection layers, e.g. formed from aluminum oxide, are disposed over metallic surfaces in order to increase the chemical stability. Conventional protection layers require high effort to provide a high protection capability since they are sensible on the quality of the metallic surface (illustratively on its cleanness) e.g. on surface contaminations (e.g. chemicals remaining from previous processes) or contaminations within its grain boundaries. Contaminations impair the deposition of the protection layer, for example, in the case the protection layer is formed by atomic layer deposition (ALD), and therefore impair the protection capability and robustness of the protection layer with respect of further processing steps. Conventional protection layers require narrow process windows to achieve the desired protection capability and compatibility to further process steps, e.g. contactability for wire bonding.

Alternatively, conventional protection layers may be based on semiconductor material. Semiconductor based protection layers exhibit a brittle structure and therefore prone to crack formation, e.g. during power Cu ratcheting, which impairs their compatibility to a wide range of further processing steps.

### SUMMARY

A semiconductor device may include: a substrate; a metallization layer disposed at least one of in or over the substrate; a protection layer disposed at least partially over the metallization layer, wherein the metallization layer includes at least one of: copper, aluminum, gold, silver; and wherein the protection layer includes a nitride material including at least one of: copper, aluminum, gold, silver.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A and FIG. 1B respectively show a semiconductor device according to various embodiments in a method according to various embodiments in a schematic side view or a schematic cross-sectional view;

FIG. 2A and FIG. 2B respectively show a semiconductor device according to various embodiments in a method according to various embodiments in a schematic side view or a schematic cross-sectional view;

FIG. 3A to FIG. 3C respectively show a protection layer according to various embodiments in a method according to various embodiments in a schematic side view or a schematic cross-sectional view;

FIG. 4A to FIG. 4C respectively show a protection layer according to various embodiments in a method according to various embodiments in a schematic side view or a schematic cross-sectional view;

FIG. 5 shows composition characteristics according to various embodiments in a method according to various embodiments in a schematic diagram;

FIG. 6A to FIG. 6C respectively show a semiconductor device according to various embodiments in a method according to various embodiments in a schematic side view or a schematic cross-sectional view;

FIG. 7A and FIG. 7B respectively show a semiconductor device according to various embodiments in a method according to various embodiments in a schematic side view or a schematic cross-sectional view;

FIG. 8A to FIG. 8C respectively show a semiconductor device according to various embodiments in a method according to various embodiments in a schematic side view or a schematic cross-sectional view;

FIG. 9A to FIG. 9C respectively show a semiconductor device according to various embodiments in a method according to various embodiments in a schematic side view or a schematic cross-sectional view;

FIG. 10A to FIG. 10C respectively show a semiconductor device according to various embodiments in a method according to various embodiments in a schematic side view or a schematic cross-sectional view;

FIG. 11A and FIG. 11B respectively show a semiconductor device according to various embodiments in a method according to various embodiments in a schematic side view or a schematic cross-sectional view;

FIG. 12A and FIG. 12B respectively show a semiconductor device according to various embodiments in a method according to various embodiments in a schematic side view or a schematic cross-sectional view;

FIG. 13A and FIG. 13B respectively show a semiconductor device according to various embodiments in a method according to various embodiments in a schematic side view or a schematic cross-sectional view;

FIG. 14A shows a layer arrangement according to various embodiments in a method according to various embodiments in a schematic side view or a schematic cross-sectional view;

FIG. 14B shows a semiconductor device according to various embodiments in a method according to various embodiments in a schematic side view or a schematic cross-sectional view; and

FIG. 15 shows a method according to various embodiments in a schematic flow diagram.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

The term “lateral” used with regards to the “lateral” extension of a structure (or of a substrate, a wafer, or a carrier) or “laterally” next to, may be used herein to mean an extension or a positional relationship along a surface of a substrate (e.g. a wafer, or a carrier). That means that a surface of a substrate (e.g. a surface of a carrier, or a surface of a wafer) may serve as reference, commonly referred to as the main processing surface of the substrate (or the main processing surface of the carrier or wafer). Further, the term “width” used with regards to a “width” of a structure (or of a structure element) may be used herein to mean the lateral extension of a structure. Further, the term “height” used with regards to a height of a structure (or of a structure element), may be used herein to mean an extension of a structure along a direction perpendicular to the surface of a substrate (e.g. perpendicular to the main processing surface of a substrate). The term “thickness” used with regards to a “thickness” of a layer may be used herein to mean the spatial extension of the layer perpendicular to the surface of the support (the material) on which the layer is deposited. If the surface of the support is parallel to the surface of the substrate (e.g. to the main processing surface) the “thickness” of the layer deposited on the support may be the same as the height of the layer. Further, a “vertical” structure may be referred to as a structure extending in a direction perpendicular to the lateral direction (e.g. perpendicular to the main processing surface of a substrate) and a “vertical” extension may be referred to as an extension along a direction perpendicular to the lateral direction (e.g. an extension perpendicular to the main processing surface of a substrate).

According to various embodiments, the semiconductor device may include one or more integrated circuit structures (also referred to as semiconductor chip, IC, chip, or microchip) which are formed during semiconductor device fabrication (in other words, in a method for forming the semiconductor device). An integrated circuit structure may be processed at least partially at least one of over or in a substrate in corresponding regions of the substrate (also referred to as active chip regions) utilizing various semiconductor processing technologies. An integrated circuit structure may include one or more (e.g. a plurality of) electrical circuit components, such among others may be at least one of transistors, resistors, capacitors, which are electrically interconnected and configured to perform operations, e.g. computing or storage operations, in the completely processed integrated circuit structure. In further semiconductor device fabrication a plurality of semiconductor devices may be singulated from the substrate after the semiconductor device processing by wafer-dicing to provide a plurality of singulated semiconductor devices (also referred to as semiconductor chips) from the plurality of semiconductor devices of the substrate. Further, a final stage of semiconductor device fabrication may include packaging (also referred to as assembly, encapsulation, or seal) of singulated semiconductor devices, wherein a singulated semiconductor device may be encased, e.g. into a supporting material (also referred to as molding material or encapsulation material) to prevent physical damage and/or corrosion of the semiconductor device. The supporting material encases the semiconductor device (illustratively, forms a package or mold) and may optionally support the electrical contacts and/or a lead frame to connect the semiconductor device to a peripheral device, e.g. to a circuit board.

According to various embodiments, during semiconductor device fabrication, various material types may be processed to form at least one of: an integrated circuit structure, electrical circuit components, contact pads, electrical interconnections, such among other may be electrically insulating materials, electrically semiconducting materials (also referred to as semiconductor material) or electrically conductive materials (also referred to as electrically conducting materials).

According to various embodiments, a substrate (also referred to as carrier or wafer) may include or be formed from at least one semiconductor material of various types, including a group IV semiconductor (e.g. silicon (Si) or germanium (Ge)), a group III-V semiconductor (e.g. gallium arsenide), or other semiconductor types, including group III semiconductors, group V semiconductors or polymers, for example. In various embodiments, the substrate is made of silicon (doped or undoped), in alternative embodiments, the substrate is a silicon on insulator (SOI) wafer. As an alternative, any other suitable semiconductor material may be used for the substrate, for example semiconductor compound material such as gallium phosphide (GaP), indium phosphide (InP), but also any suitable ternary semiconductor compound material or quaternary semiconductor compound material such as indium gallium arsenide (InGaAs). A semiconductor material, layer, region or the like may be understood as having moderate electrical conductivity, e.g. an electrical conductivity (measured at room temperature and constant electric field direction, e.g. constant electric field) in the range from about 10⁻⁶ S/m to about 10⁶ S/m.

According to various embodiments, an electrically conductive material, layer, region or the like may include or may be formed from a metallic material (e.g. a metal or a metal alloy), a silicide (e.g. titanium silicide, molybdenum silicide, tantalum silicide or tungsten silicide), a conductive polymer, a polycrystalline semiconductor (e.g. polycrystalline silicon also referred to as polysilicon), or a highly doped semiconductor (e.g. highly doped silicon). An electrically conductive material, layer, region or the like may be understood as having good electrical conductivity, e.g. an electrical conductivity (measured at room temperature and constant electric field direction, e.g. constant electric field) larger than about 10⁶S/m, e.g. larger than about 5·10⁶S/m, or as having high electrical conductivity, e.g. larger than about 10⁷S/m, e.g. larger than about 5·10⁷S/m.

According to various embodiments, a metal refers to a chemical element (e.g. a metalloid, a transition metal, a post-transition metal, an alkali metal or an alkaline earth metal), such as tungsten (W), aluminum (Al), copper (Cu), nickel (Ni), magnesium (Mg), chromium (Cr), iron (Fe), zinc (Zn), tin (Sn), gold (Au), silver (Ag), iridium (Ir), platinum (Pt), indium (In), cadmium (Cd), bismuth (Bi), vanadium (V), titanium (Ti), palladium (Pd), or zirconium (Zr).

A metal alloy may include at least two a metals (e.g. two or more than two metals, e.g. in the case of an intermetallic compound) or at least one metal (e.g. one or more than one metal) and at least one other chemical element (e.g. a non-metal or a half metal). For example, a metal alloy may include or may be formed from at least one metal and at least one non-metal (e.g. carbon (C) or nitrogen (N)), e.g. in the case of steel or a nitride. For example, a metal alloy may include or may be formed from more than one metal (e.g. two or more metals), e.g. various compositions of gold with aluminum, various compositions of copper with aluminum, various compositions of copper and zinc (e.g. “brass”) or an various compositions of copper and tin (e.g. “bronze”), e.g. including various intermetallic compounds.

An electrically insulating (e.g. dielectric) material, layer, region or the like may be understood as having poor electrical conductivity, e.g. an electrical conductivity (measured at room temperature and constant electric field direction) smaller than about 10⁻⁶ S/m, e.g. smaller than about 10⁻⁸ S/m, e.g. smaller than about 10⁻¹⁰ S/m.

An electrically insulating material may include or be formed from a semiconductor oxide, a metal oxide, a ceramic, a semiconductor nitride, a semiconductor carbide, a glass, e.g. fluorosilicate glass (FSG), a polymer, e.g. a resin, an adhesive, a resist, benzocyclobutene (BCB) or polyimide (PI), a silicate, e.g. hafnium silicate or zirconium silicate, a transition metal oxide, e.g. hafnium dioxide or zirconium dioxide, an oxynitride, e.g. silicon oxynitride, or any other dielectric material types.

An electrically conductive layer may be understood to include (e.g. predominantly) or be formed from an electrically conductive material. An electrically insulating layer may be understood to include (e.g. predominantly) or be formed from an electrically insulating material. A metallic layer may be understood to include (e.g. predominantly) or be formed from a metallic material.

According to various embodiments, a protection layer is provided including or formed from a nitride material (e.g. CuₓN_{y}) including a metal and nitrogen, also referred as to metal nitrite. Illustratively, the protection layer simplifies the fabrication process, reduces material costs, and simplifies the required fabrication equipment. Further, the protection layer may provide at least one of the following: a uniform layer over the whole substrate which is conform to the surface topography, a strong mechanical interface to other layers (e.g. an imide layer or a adhesion layer passivation), chemical robustness regarding further process steps (e.g. plasma supported processes, organic solvents supported processes), a bondable surface, an electrically conducting surface for plating, an oxygen-proof surface, a humidity-proof surface, a temperature-proof surface. Further process steps may include integration processes such as forming a polyimide layer, forming an epoxy passivation, die attach, wire bonding, plating, packaging, sawing or dicing.

According to various embodiments, a protective layer (e.g. with a thickness less than about 40 nm) is provided, which may be formed using reactive direct current (DC) magnetron sputtering. The protective layer may be directly formed after forming a metallization layer (e.g. a Cu-seed layer, an electroplated Cu layer or a Cu power metal deposition in a front end process). Illustratively, the protection layer provides a surface which is highly robust regarding chemical attacks such as high humidity (e.g. greater than about 95%) or high temperature (e.g. greater than about 60° C.), and may be stable for a long time period (e.g. for greater than about 15 months) or may withstand a combination of chemical attacks (e.g. a high temperature greater than about 100° C. for many months). The protection layer may be stable without discoloration or oxidation.

According to various embodiments, the protection layer may replace other layers, which are conventionally used in the device fabrication. Illustratively, the protection layer may provide good adhesion to other materials like polymers (e.g. polyimide) and metals and/or may provide good barrier properties. Therefore, the protection layer may replace conventional semiconductor nitride layers, oxide layer and semiconductor carbide layers. For example, the protection layer may replace silicon nitride (SNIT), e.g. may be used as an adhesion layer instead of SNIT, e.g. for Cu based technologies. For example, the protection layer may replace thin (e.g. about 40 nm) SNIT layers which are used as an interface layers in several front end (FE) technologies. For example, the protection layer may replace SiC layers which are used as barrier layers in several front end (FE) technologies. For example, the protection layer may replace a thin (e.g. less than 10 nitride material thick) AlOₓ layer.

The protection layer may provide to be tuned in its physical properties (e.g. electrical properties) in a method according to various embodiments. For example, the protection layer provides a semiconducting behavior at a certain composition (e.g. including or formed from Cu₃N, in other words with a nitrogen concentration of 25 at. %) and/or at a certain layer thickness (e.g. greater than about 1 μm thickness). With decreasing nitrogen concentration (e.g. starting at the nitrogen concentration of greater than about 25 at. %) the electrical conductivity of the protection layer increases, e.g. reaching values comparable to pure metal (like pure Cu). The composition of the protection layer may be adjusted by heating. When the temperature of the protection layer exceeds a critical value (illustratively at higher temperatures), the nitrogen concentration decreases with at least one of increasing time, increasing temperature. Finally, the protection layer may provide metallic behavior. Illustratively, adjusting the composition of the protection layer increases its integrability into semiconductor device fabrication and its compatibility with further process steps. For example, the composition of the protection layer be adjusted to a nitrogen concentration of greater than 20 at. %, which illustratively provides a high robust surface and protection of the metallization layer against further process steps.

According to various embodiments, using the protection layer may speed up the process and may reduce process costs, since the process steps may be reduced. For example, additional etching in order to remove metal oxide layer may be not necessary (e.g. prior bonding or formation of following layer), or formation of SiN may be not necessary. Additionally, the protection layer may be formed fast and cost efficient, e.g. using at least one of reactive magnetron sputtering and ALD for forming the protection layer.

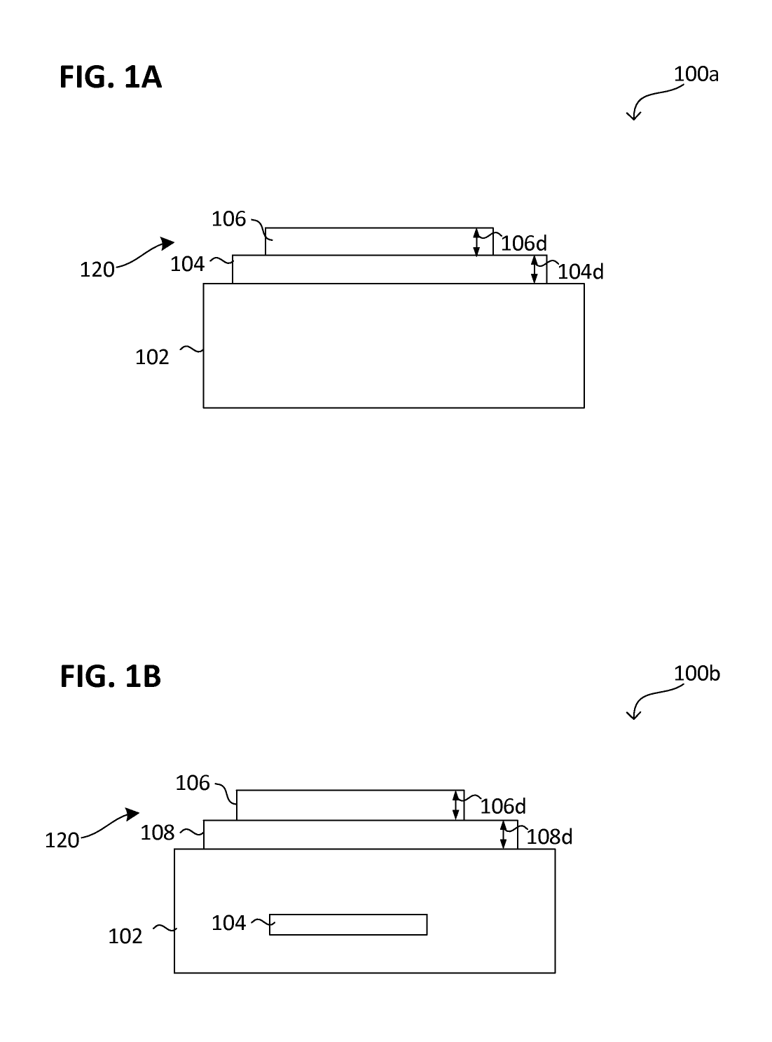

FIG. 1A illustrates a semiconductor device 100a according to various embodiments in a method according to various embodiments in a schematic side view or a schematic cross-sectional view.

The semiconductor device 100a may include a substrate 102, e.g. a semiconductor substrate 102. A semiconductor substrate 102 may include or be formed from a semiconductor material, e.g. Si. Further, the semiconductor device 100a may include a metallization layer 104 (also referred to as first metallization layer 104) disposed or formed in or over the substrate 102. Further, the semiconductor device 100a may include a protection layer 106 disposed or formed at least partially over the metallization layer 104. The metallization layer 104 may be formed at least partially in direct physical contact with the substrate 102. Alternatively or additionally, at least one additional layer may be formed at least partially (in other words partially or completely) extending between the metallization layer 104 and the substrate 102. The protection layer 106 may be formed at least partially in direct physical contact with the metallization layer 104. Alternatively or additionally, at least one additional layer may be formed at least partially extending between the protection layer 106 and the metallization layer 104.

According to various embodiments, the metallization layer 104 includes or is formed from at least one metal (also referred to as first metal) of the following metals: copper, aluminum, gold, and silver. Optionally, the metallization layer 104 includes or is formed from a metal alloy (first metal alloy) including at least one metal of the following metals: copper, aluminum, gold, and silver. The metal alloy of the metallization layer 104 may optionally include alloying elements, such as Mg, Al, Zn, Zr, Sn, Ni, Pd, Si.

The protection layer 106 includes or is formed from a nitride material. The nitride material may include at least one metal of the following metals: copper, aluminum, gold, silver, the first metal. The nitride material may be a nitride of the metal (also referred as metal nitride), in other words, a chemical compound of nitrogen with metal. The nitride material may include or be formed from at least the metal and nitrogen (N). According to various embodiments, the metal of the metallization layer 104 is copper (Cu) and the nitride material may be copper nitride (CuₓN_{y}).

For example, the metallization layer 104 and the nitride material may include the same metal, e.g. copper, aluminum, gold or silver. This allows for a better integration of the protection layer 106 into the fabrication process of the semiconductor device 100a, at least since existing deposition techniques and materials may be used for both, the metallization layer 104 and the protection layer 106.

The metallization layer 104 may include predominately the metal (in other words the metallization layer 104 may be formed substantially from the metal), for example, a concentration (atomic concentration) of the metal in the metallization layer 104 may be greater than about 60 atomic percent (at. %) and alternatively or additionally less or equal to 100 at. % (e.g. in a range from about 60 at. % to 100 at. %), e.g. greater than about 70 at. %, e.g. greater than about 80 at. %, e.g. greater than about 90 at. %, e.g. greater than about 95 at. %, e.g. greater than about 99 at. %. The concentration may be understood as the percentage of a number of atom relative to the total number of atoms in a material, a layer, a region or the like. For example, the metallization layer 104 may include or may be formed from copper. Optionally, the metallization layer 104 may include or may be formed from a metal alloy including copper (e.g. a Cu-alloy).

The protection layer 106 may include predominately the nitride material (in other words the protection layer 106 may be formed substantially from the nitride material), for example, a concentration (atomic concentration) of the nitride material in the protection layer 106 may be greater than about 60 atomic percent (at. %) and alternatively or additionally less or equal to 100 at. % (e.g. in a range from about 60 at. % to 100 at. %), e.g. greater than about 70 at. %, e.g. greater than about 80 at. %, e.g. greater than about 90 at. %, e.g. greater than about 95 at. %, e.g. greater than about 99 at. %. For example, the protection layer 106 may include or may be formed from a nitride material including copper.

According to various embodiments, the protection layer 106 may be at least partially (that means at least a portion of the protection layer 106 may be) exposed, e.g. to environmental influences. In other words, at least a portion of the protection layer 106 may be uncovered. The protection layer 106 may be configured to provide chemical stability regarding environmental influences, such as oxygen, solvents, abrasive, etchants, humidity, temperature, etc., that means without substantial changes in at least one of a chemical composition, physical properties, chemical bonding (for example, decomposition, recrystallization). For example, the protection layer 106 may provide corrosion resistance, e.g. in ambient conditions above 350° C. Illustratively, the protection layer 106 may be self-stable.

The protection layer may include a thickness 106d (protection layer thickness 106d) and the metallization layer 104 may include a thickness 104d (metallization layer thickness 104d). According to various embodiments, the protection layer thickness 106d may be less than or equal to the metallization layer thickness 104d, e.g. less than or equal to about 50% of the metallization layer thickness 104d, e.g. less than or equal to about 10% of the metallization layer thickness 104d, e.g. less than or equal to about 1% of the metallization layer thickness 104d, e.g. less than or equal to about 0.1% of the metallization layer thickness 104d, e.g. less than or equal to about 0.01% of the metallization layer thickness 104d.

According to various embodiments, the protection layer thickness 106d may be less than or equal to about 1 micrometer (μm) and alternatively or additionally greater than about 0.01 nm, e.g. less than or equal to about 0.5 μm, e.g. less than or equal to about 0.4 μm, e.g. less than or equal to about 0.3 μm, e.g. less than or equal to about 0.2 μm, e.g. less than or equal to about 0.1 μm (corresponding to 100 nm), e.g. less than or equal to about 50 nanometer (nm), e.g. less than or equal to about 40 nm, e.g. less than or equal to about 30 nm, e.g. less than or equal to about 20 nm, e.g. less than or equal to about 10 nm, e.g. less than or equal to about 5 nm. According to various embodiments, the protection layer thickness may be greater than or equal to about 0.01 nm (e.g. in form of an atomic monolayer), e.g. greater than or equal to about 0.05 nm, e.g. greater than or equal to about 0.1 nm, e.g. greater than or equal to about 0.5 nm, e.g. greater than or equal to about 1 nm, e.g. greater than or equal to about 2 nm. For example, the protection layer thickness may be in the range from about 5 nm to about 0.5 μm, e.g. in the range from about 10 nm to about 0.2 μm, e.g. in the range from about 20 nm to about 100 nm.

At least the metallization layer 104 and the protection layer 106 may be part of a layer arrangement 120, as described in the following in detail.

FIG. 1B illustrates a semiconductor device 100b according to various embodiments in a method according to various embodiments in a schematic side view or a schematic cross-sectional view. The semiconductor device 100b may be similar to the semiconductor device 100a, wherein in the semiconductor device 100b the metallization layer 104 (first metallization layer 104) may be disposed or formed at least partially in the substrate 102, e.g. buried into the substrate 102. According to various embodiments, the substrate 102 may be a semiconductor substrate 102.

According to various embodiments, the semiconductor device 100b may include a further metallization layer 108 (also referred to as second metallization layer 108) formed over the substrate 102, e.g. on the substrate 102. Alternatively, the second metallization layer 108 may be formed at least partially in the substrate 102 (not illustrated), e.g. buried into the substrate 102. The second metallization layer 108 may be disposed or formed between the first metallization layer 104 and the protection layer 106, e.g. between the substrate 102 and the protection layer 106.

The second metallization layer 108 may include or be formed from a further metal (second metal). Optionally, the second metallization layer 108 may include or be formed from a metal alloy (second metal alloy) including the second metal. The second metal may be at least one of the following metals: Al, Cu, Au, Ag, the first metal. The second metallization layer 108 may include predominately the second metal (in other words is formed substantially from the second metal), for example, a concentration (atomic concentration) of the second metal in the second metallization layer 104 may be greater than about 60 at. % and alternatively or additionally less or equal to 100 at. % (e.g. in a range from about 60 at. % to 100 at. %), e.g. greater than about 70 at. %, e.g. greater than about 80 at. %, e.g. greater than about 90 at. %, e.g. greater than about 95 at. %, e.g. greater than about 99 at. %. For example, the second metallization layer 108 may include or may be formed from a metal alloy including the second metal, e.g. an Al-alloy or a Cu-alloy, and optionally including alloying elements, such as Si, Mg, Al, Zn, Zr, Sn, Ni, Pd, Ag, or Au.

The second metallization layer 108 may be formed at least partially in direct physical contact with the substrate 102. Alternatively or additionally, at least one additional layer may be formed at least partially (in other words partially or completely) extending between the second metallization layer 108 and the substrate 102. The protection layer 106 may be formed at least partially in direct physical contact with the second metallization layer 108. Alternatively or additionally, at least one additional layer may be formed at least partially extending between the protection layer 106 and the second metallization layer 108.

In this configuration, the second metallization layer 108 may include or be formed from a final metallization, e.g. including a contact pad (e.g. a bonding pad), and the first metallization layer 104 may include or be formed from an interlayer metallization, e.g. for contacting a circuit component, e.g. being in electrical contact to the second metallization layer 108.

According to various embodiments, at least one of the first metallization layer 104, the second metallization layer 108 may be electrically conductive, e.g. including an electrical conductivity (measured at room temperature and constant electric field direction) larger than about 10⁶ Sievert per meter (S/m), e.g. larger than about 5·10⁶ S/m, e.g. larger than about 10⁷S/m, e.g. larger than about 5·10⁷S/m.

The second metallization layer 108 may include a thickness 108d (second metallization layer thickness 104d). According to various embodiments, the protection layer thickness 106d may be less than or equal to the second metallization layer thickness 108d, e.g. less than or equal to about 50% of the second metallization layer thickness 108d, e.g. less than or equal to about 10% of the second metallization layer thickness 108d, e.g. less than or equal to about 1% of the second metallization layer thickness 108d, e.g. less than or equal to about 0.1% of the second metallization layer thickness 108d, e.g. less than or equal to about 0.01% of the second metallization layer thickness 108.

At least the first metallization layer 104, the second metallization layer 108 and the protection layer 106 may be part of a layer arrangement 120.

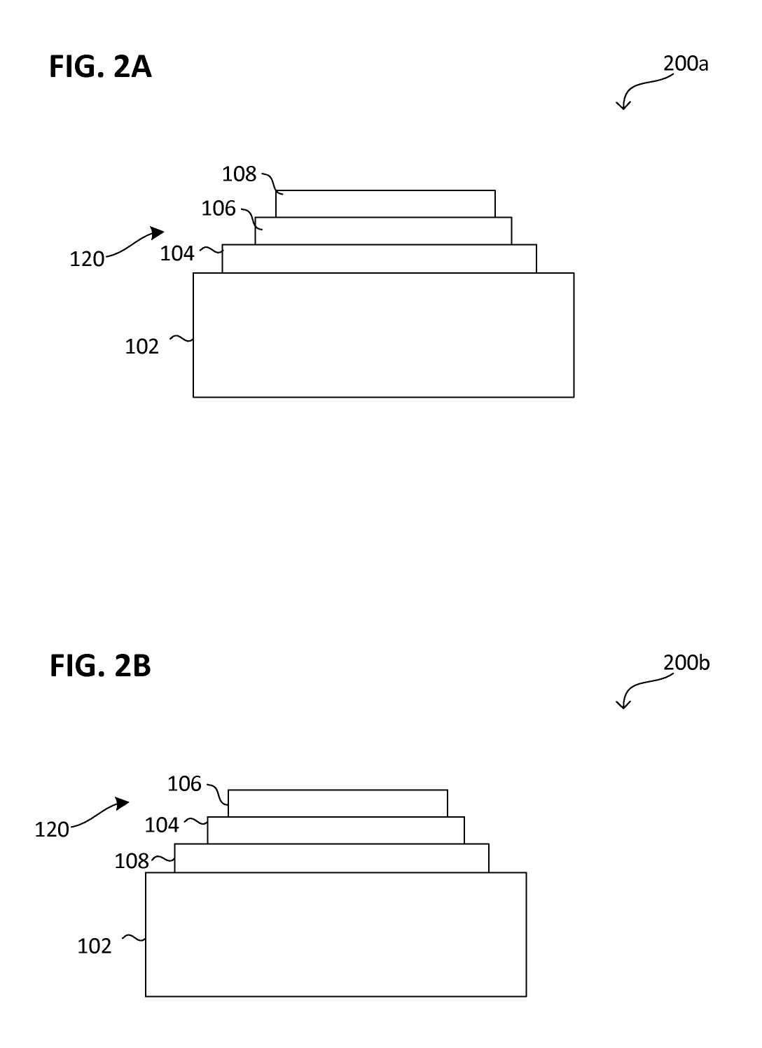

FIG. 2A illustrates a semiconductor device 200a according to various embodiments in a method according to various embodiments in a schematic side view or a schematic cross-sectional view. The semiconductor device 200a may be similar to the semiconductor device 100a, wherein the semiconductor device 200a may additionally include the second metallization layer 108.

According to various embodiments, the second metallization layer 108 may be disposed or formed over the protection layer 106. The protection layer 106 may be formed at least partially in direct physical contact with the second metallization layer 108. Alternatively or additionally, at least one additional layer may be formed at least partially extending between the protection layer 106 and the second metallization layer 108.

This configuration may be beneficial for various implementations. For example, the first metallization layer 104 and the second metallization layer 108 may include or be formed from a redistribution layer (e.g. formed by plating), wherein the protection layer 106 may include or be formed from an interlayer. Alternatively, the first metallization layer 104 may include or be formed from a seed layer (e.g. including a thickness of less than about 10 nm) and the second metallization layer 108 may be formed by plating over the seed layer, e.g. using the seed layer as electrode and pattern. Alternatively, the second metallization layer 108 may include or be formed from a final metallization, e.g. including a contact pad (e.g. a bonding pad) and the first metallization layer 104 may include or be formed from a interlayer metallization, e.g. for contacting a circuit component or another metallization layer, or the first metallization layer 104 may include or be formed from a redistribution layer, e.g. for interconnecting a plurality of circuit components with each other, e.g. to form an integrated circuit structure.

At least the first metallization layer 104, the second metallization layer 108 and the protection layer 106 may be part of a layer arrangement 120, as described herein.

FIG. 2B illustrates a semiconductor device 200b according to various embodiments in a method according to various embodiments in a schematic side view or a schematic cross-sectional view. The semiconductor device 200b may be similar to the semiconductor device 100a, wherein the semiconductor device 200a may additionally include the second metallization layer 108.

According to various embodiments, the second metallization layer 108 may be disposed or formed between the first metallization layer 104 and the substrate 102. The second metallization layer 108 may be formed at least partially in direct physical contact with the substrate 102. Alternatively or additionally, at least one additional layer may be formed at least partially extending between the second metallization layer 108 and the substrate 102. The first metallization layer 104 may be formed at least partially in direct physical contact with the second metallization layer 108. Alternatively or additionally, at least one additional layer may be formed at least partially extending between the first metallization layer 104 and the second metallization layer 108. The protection layer 106 may be formed at least partially in direct physical contact with the first metallization layer 104. Alternatively or additionally, at least one additional layer may be formed at least partially extending between the protection layer 106 and the first metallization layer 104.

At least the first metallization layer 104, the second metallization layer 108 and the protection layer 106 may be part of a layer arrangement 120.

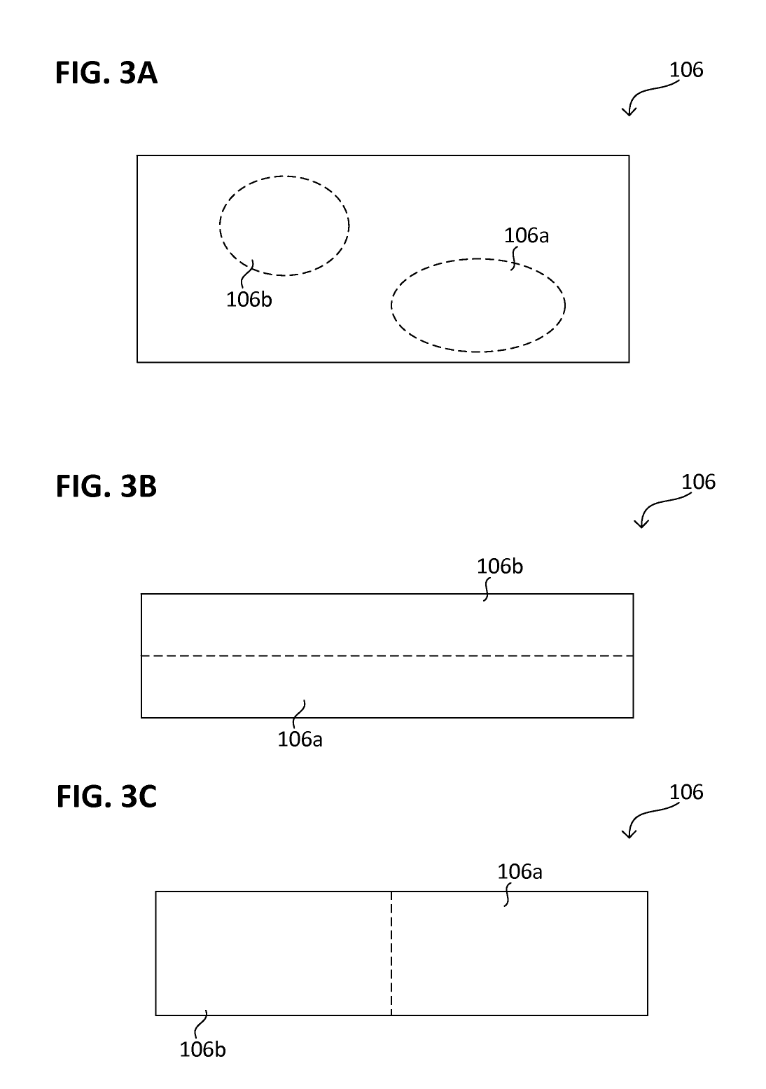

FIG. 3A to FIG. 3C respectively illustrate a protection layer 106 according to various embodiments in a method according to various embodiments in a schematic side view or a schematic cross-sectional view.

The protection layer 106 may include or be formed from at least a first region 106a and a second region 106b. The first region 106a and the second region 106b may differ from each other by at least a chemical composition, e.g. by a concentration of nitrogen or an atomic ratio.

For example, a first concentration of nitrogen (first nitrogen concentration) of the protection layer 106 in its first region 106a is different from a second concentration of N (second nitrogen concentration) of the protection layer 106 in its second region 106b. The nitrogen concentration may be understood as the percentage of a number of nitrogen atom relative to the total number of atoms in a material, a layer, a region or the like (e.g. the first/second region). The first nitrogen concentration and the second nitrogen concentration may be formed by adjusting the composition (chemical composition) of the protection layer 106, e.g. adjusting at least the composition of the first region 106a and the composition of the second region 106b. Illustratively, the first region 106a may include more or less nitrogen than the second region 106b.

The nitrogen concentration may define an atomic ratio of the metal to nitrogen in a material, a layer, a region or the like. The atomic ratio of metal (M) to nitrogen (N) may be understood as percentage of a number of metal atoms relative to a number of nitrogen atoms in a material, a layer, a region or the like, e.g. in the protection layer 106, e.g. in its first region 106a and/or its second region 106b. According to various embodiments, a first atomic ratio of M to N in the first region 106a may be different from a second atomic ratio of M to N in the second region 106b. For example, the atomic ratio of copper to nitrogen in the first region 106a may be different from the atomic ratio of copper to nitrogen in the second region 106b.

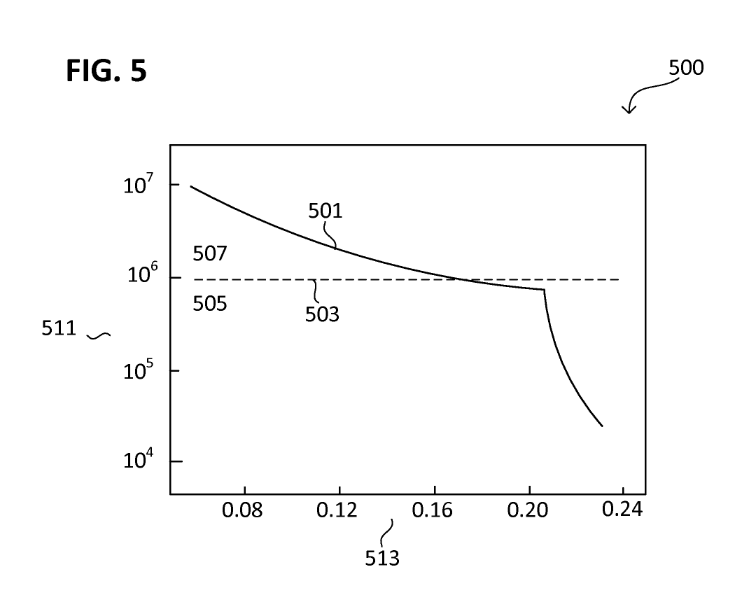

According to various embodiments, a composition (defining a nitrogen concentration or an atomic ratio of M to N, respectively) may be adjusted such (see FIG. 5), that a material, layer, region or the like is electrically conductive (e.g. with an electrical conductivity greater than about 10⁶ S/m), electrically semiconducting (e.g. with an electrical conductivity in the range from about 10⁶ S/m to about 10⁶ S/m) or electrically insulating (e.g. with an electrical conductivity less than about 10⁻⁶ S/m).

For example, a first composition (defining the first nitrogen concentration or the first atomic ratio, respectively) of the first region 106a may be adjusted such, that the first region 106a is electrically conducting. Alternatively or additionally, a second composition (defining the second nitrogen concentration or second atomic ratio, respectively) of the second region 106b may be adjusted such, that the second region 106b is electrically semiconducting.

According to various embodiments, the second region 106b and the first region 106a may include a distance between each other, as illustrated in FIG. 3A. Alternatively, the second region 106b and the first region 106a may be in physical contact to each other. Optionally, the second region 106b may be disposed (e.g. at least partially) over the first region 106a, as illustrated in FIG. 3B. For example, at least a portion of an interface between the first region 106a and the second region 106b may extend (in other words, at least sectionally) along a vertical (perpendicular to a lateral direction) direction. Alternatively or additionally, the first region 106a and the second region 106b may be disposed or formed (e.g. at least partially) laterally next to each other, as illustrated in FIG. 3C. For example, at least a portion of an interface between the first region 106a and the second region 106b may extend (in other words, at least sectionally) along the lateral direction.

According to various embodiments, the first composition is spatially substantially constant within at least the first region 106a. Alternatively or additionally, the second composition may be spatially substantially constant within at least the second region 106b. In other words, at least one of: the first region 106a and the second region 106b may include or be formed from a homogeneous composition.

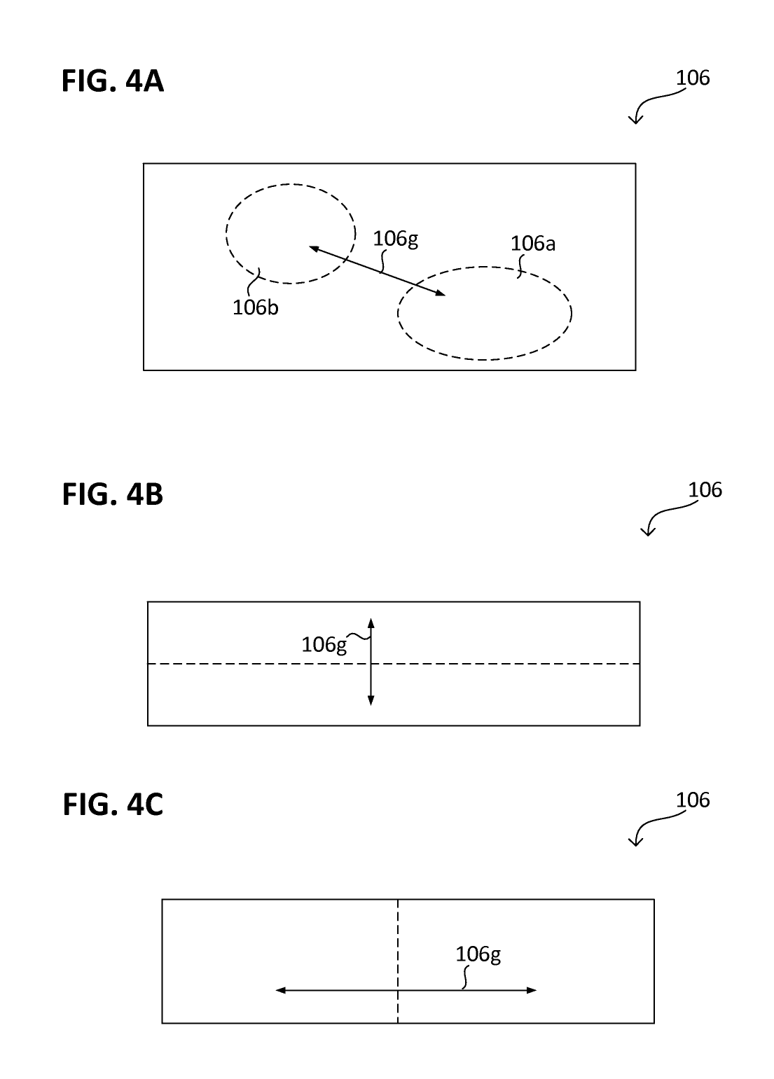

FIG. 4A to FIG. 4C respectively illustrate a protection layer 106 according to various embodiments in a method according to various embodiments in a schematic side view or a schematic cross-sectional view.

According to various embodiments, the protection layer 106 includes a composition profile 106g (defining a nitrogen concentration gradient profile or an atomic ratio gradient profile, respectively). For example, a nitrogen concentration gradient profile 106g may range at least from the first nitrogen concentration to the second nitrogen concentration. For example, an atomic ratio gradient profile 106g may range at least from the first atomic ratio to the second atomic ratio.

The composition gradient profile 106g may define a gradient direction pointing into the direction of the maximum gradient. The gradient direction may include a vertical direction component and a lateral direction component, as illustrated in FIG. 4A. Alternatively, the gradient direction may include exclusively the vertical direction component, as illustrated in FIG. 4B. Alternatively, the gradient direction may include exclusively the lateral direction component, as illustrated in FIG. 4C.

The composition gradient profile 106g may extend at least partially between the first region 106a and the second region 106b. Alternatively or additionally, the composition gradient profile 106g may extend at least partially into at least one of the first region 106a, the second region 106b. Alternatively or additionally, the composition gradient profile 106g may extend at least substantially through at least one of the first region 106a, the second region 106b

FIG. 5 illustrates composition characteristics of a protection layer according to various embodiments in a method according to various embodiments in a schematic diagram 500. In the diagram the relation 501 of electrical conductivity 511 (in S/m) is illustrated in dependency to the composition 513 (here related to the nitrogen concentration in atomic percent). The dashed line 503 illustrates the transition between an electrical conductivity range 505 in accordance with electrical semiconducting behavior (in other words an electrical semiconducting range 505) and an electrical conductivity range 507 in accordance with electrical conducting behavior (in other words an electrical conducting range 507). As illustrated in FIG. 5, the electrical conductivity 511 is increased with reduced nitrogen concentration in the protection layer, e.g. in at least one of the first region of the protection layer, the second region of the protection layer.

According to various embodiments, the protection layer (e.g. at least one of its first region 106a, its second region 106b) may include or be formed from a composition or a nitride material having a nitrogen concentration (e.g. spatially averaged) of less than about 25 at. % (corresponding to an atomic ratio of M to N of about 3), e.g. less than about 20 at. % (corresponding to an atomic ratio of M to N of about 4), e.g. less than about 16 at. % (corresponding to an atomic ratio of M to N of about 5.25), e.g. less than about 13 at. % (corresponding to an atomic ratio of M to N of about 6.7), e.g. less than about 10 at. % (corresponding to an atomic ratio of M to N of about 9), e.g. less than about 8 at. % (corresponding to an atomic ratio of M to N of about 11.5), e.g. less than about 5 at. % (corresponding to an atomic ratio of M to N of about 19), e.g. less than about 4 at. % (corresponding to an atomic ratio of M to N of about 24), e.g. less than about 2 at. % (corresponding to an atomic ratio of M to N of about 49), e.g. less than about 1 at. % (corresponding to an atomic ratio of M to N of about 99). Alternatively or additionally, the protection layer (e.g. at least one of its first region 106a, its second region 106b) may include or be formed from a composition or a nitride material having a nitrogen concentration (e.g. spatially averaged) of greater than about 0.1 at. %.

For example, when the protection layer includes or is formed from a nitride material MₓN_{y} (e.g. CuₓN_{y}), wherein M denotes a metal (e.g. Cu) of the nitride material, x denotes the concentration of the metal in the nitride material and y denotes the nitrogen concentration in the nitride material, the atomic ratio of M to N is defined by x/y.

The protection layer or at least a portion of it (e.g. at least one of its first region 106a, its second region 106b) may include or be formed from nitride material having at least one of locally varying compositions (with defined x to y ratio) and locally varying crystallinity, e.g. being substantially constant within a spatially limited volume (also referred as to grains), e.g. in nanometer, micrometer or millimeter scale (also referred as to grain size). For example, the protection layer may include or be formed from nitride material MₓN_{y} with a composition of at least one of the following compositions: M₃N, M₂N, MN, MN₂, MN₃. For example, the nitride material CuₓN_{y} may include or be formed from at least one of the following compositions: Cu₃N, Cu₂N, CuN, CuN₂ and CuN₃. Alternatively or additionally, the protection layer may include metal inclusions (e.g. Cu inclusions), e.g. precipitates. For example, Cu inclusions may be distributed in a Cu₃N matrix. The distribution and composition of the grains of the protection layer may define the (e.g. spatially averaged) composition (nitrogen concentration or atomic ratio, respectively) of the protection layer, e.g. of its nitride material.

As illustrated in FIG. 5, a nitrogen concentration of less than 20 at. % results in a transition from electrically semiconducting behavior 505 into electrically conducting behavior 507. The composition of the protection layer, e.g. at least one of its first region and its second region, may be adjusted in accordance with a predetermined conduction behavior. For example, the first region may include a greater electrical conductivity than the second region. In this case, the first atomic ratio may be greater than the second atomic ratio. In other words, the first nitrogen concentration may be less than the second nitrogen concentration.

According to various embodiments, the first region of the protection layer may include or be formed from a composition in accordance with an electrically conducting behavior. In this case, the first atomic ratio is equal to or greater than about 4, e.g. equal to or greater than about 5, e.g. equal to or greater than about 6, e.g. equal to or greater than about 7, e.g. equal to or greater than about 8, e.g. equal to or greater than about 9, e.g. equal to or greater than about 10, e.g. equal to or greater than about 15, e.g. equal to or greater than about 20, e.g. equal to or greater than about 50, e.g. in a range from about 4 to about 100, e.g. in a range from about 5 to about 20.

According to various embodiments, the second region of the protection layer may include or be formed from a composition in accordance with an electrically semiconducting behavior. In this case, the second atomic ratio is less than about 4, e.g. in a range from about 3 to about 4.

The process parameter for forming the protection layer (e.g. the nitride material) may influence the grain size in the protection layer. For example, the grain size may increase with increasing temperature during forming the protection layer, e.g. from a small grain size (about 30 nm to about 50 nm) up to a grain size of about 200 nm. For example, the protection layer may include a plurality of grains in a polycrystalline order.

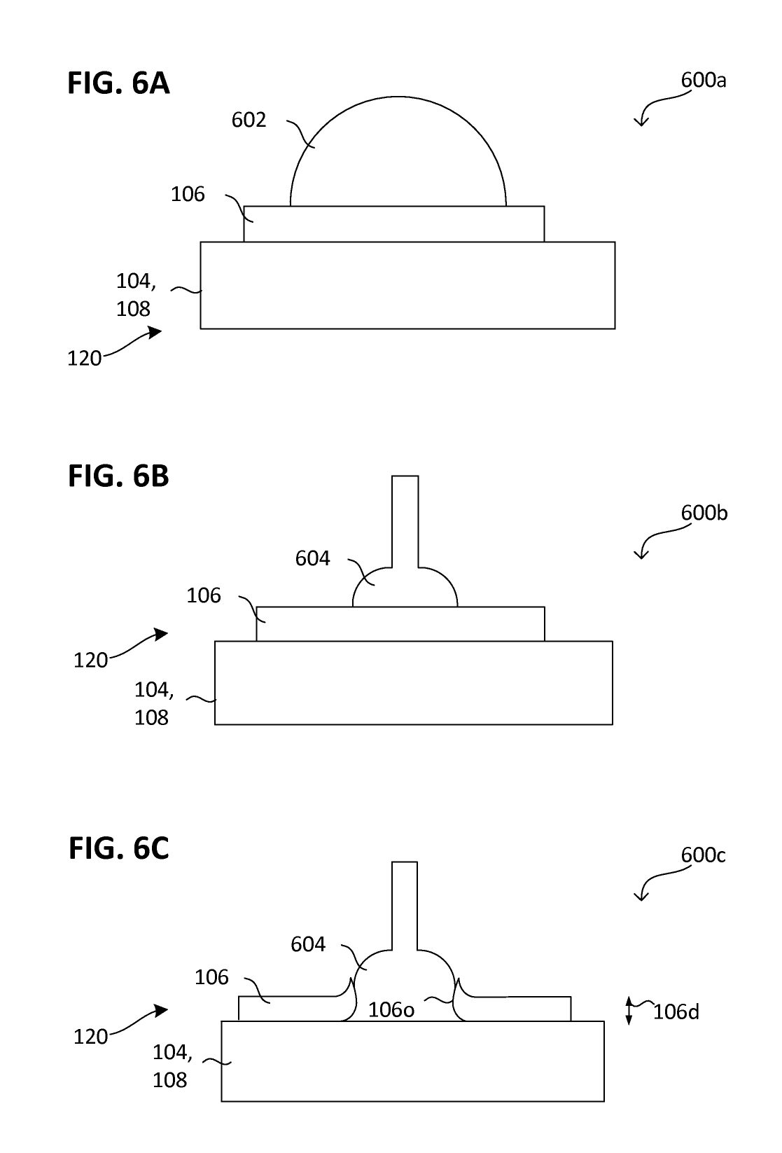

FIG. 6A illustrates a semiconductor device 600a according to various embodiments in a method according to various embodiments in a schematic side view or a schematic cross-sectional view.

According to various embodiments, the semiconductor device 600a may include a solder joint 602 disposed or formed at least partially over the protection layer 106. The solder joint 602 may be disposed or formed at least partially in direct physical contact with the protection layer 106. Alternatively or additionally, at least one additional layer may be formed at least partially extending between the solder joint 602 and the protection layer 106.

The solder joint 602 may include or be formed from a solder material. The solder material may include or be formed from at least one metal (also referred to as third metal) of the following metals: Pb, Sn, Ag, Al. Optionally, the solder material may include or be formed from a metal alloy (also referred as to solder alloy) including at least one metal of the following metals: Pb, Sn, Ag, Al. For example, the solder alloy may be a Sn based solder alloy or a Pb based solder alloy. The solder alloy may optionally include alloying elements, such as Mg, Zn, Zr, Ni, Pd, or Au.

Optionally, the protection layer 106 may include an electrically conducting first region, which extends at least partially from the underlying metallization layer 104, 108 (at least one of the first metallization layer 104 and the second metallization layer 108) to the solder joint 602, e.g. being in physical contact with both.

FIG. 6B illustrates a semiconductor device 600b according to various embodiments in a method according to various embodiments in a schematic side view or a schematic cross-sectional view.

According to various embodiments, the semiconductor device 600a may include a bonding joint 604 formed or disposed at least partially over the protection layer 106. The bonding joint 604 may be formed at least partially in direct physical contact with the protection layer 106. Alternatively or additionally, at least one additional layer may be formed at least partially extending between the bonding joint 604 and the protection layer 106.

The bonding joint 604 may include or be formed from a bonding material. The bonding material may include or be formed from at least one metal (also referred to as fourth metal) of the following metals: Ag, Al, Au, Cu. Optionally, the bonding material may include or be formed from a metal alloy (also referred as to bonding alloy) including at least one metal of the following metals: Ag, Al, Au, Cu. For example, the bonding alloy may be an Ag based alloy (in other words, an alloy including predominantly Ag) or an Al based alloy. The bonding alloy may optionally include alloying elements, such as Mg, Zn, Zr, Sn, Ni, and Pd.

In this case, the protection layer 106 may include or be formed from electrically conducting nitride material, which extends at least partially from the underlying metallization layer 104, 108 to the bonding joint 604, e.g. being in physical contact with both.

FIG. 6C illustrates a semiconductor device 600c according to various embodiments in a method according to various embodiments in a schematic side view or a schematic cross-sectional view.

According to various embodiments, the protection layer 106 may include an opening 106o, which at least partially may expose the underlying metallization layer 104, 108. In this case, the bonding joint 604 may extend at least partially through (in other words, into or through) the protection layer 106. For example, the bonding joint 604 may be in physical contact to the underlying metallization layer 104, 108 if extending through the protection layer 106. In this case, the protection layer 106 may include or be formed from an electrically insulating nitride material, e.g. at least partially surrounding the opening 106o.

According to various embodiments, a thickness of the protection layer 106d is less than about 0.1 μm and alternatively or additionally greater than about 0.01 nm. This enables to crack the protection layer 106 via the bonding process, e.g. by bonding on the protection layer 106d. This may also be referred as to bonding through the protection layer 106. In other words, the opening 106o may be formed by applying mechanical load to the protection layer 106 which arises from bonding (illustratively, scraping). Alternatively, the opening 106o may be formed by removing material from the protection layer 106, e.g. by at least one of ablation and etching.

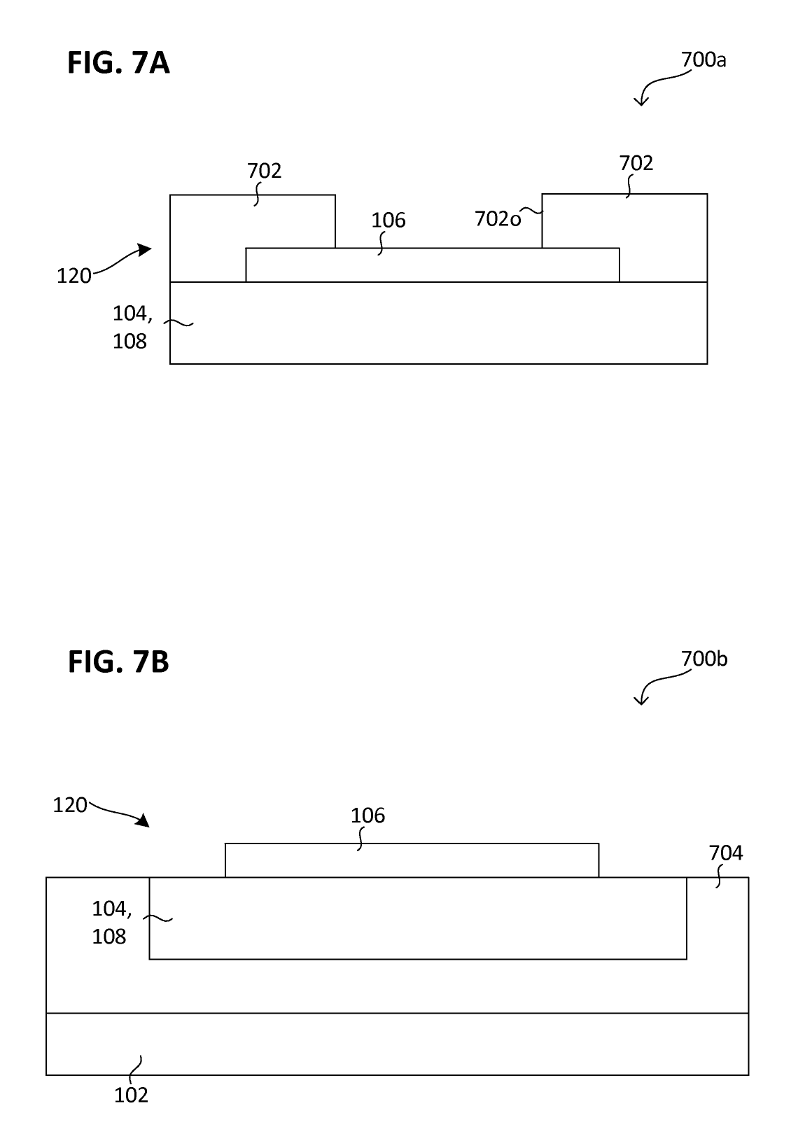

FIG. 7A illustrates a semiconductor device 700a according to various embodiments in a method according to various embodiments in a schematic side view or a schematic cross-sectional view.

The semiconductor device 700a may include a polymer layer 702 disposed or formed at least partially over the protection layer 106. The polymer layer 702 may optionally be formed or disposed at least partially over the underlying metallization layer 104, 108.

The polymer layer 702 may include or be formed from least one polymer of the following polymers: an imide, a resin, an epoxy, a mold compound, an adhesive. For example, the polymer layer 702 may include or be formed from an adhesive layer (e.g. formed from an adhesive). Alternatively or additionally, the polymer layer 702 may include or be formed from as mask (e.g. formed from resin). Alternatively or additionally, the polymer layer 702 may include or be formed from a passivation layer (e.g. formed from an imide or a mold compound).

According to various embodiments, the polymer layer 702 may include an opening 702o which may at least partially expose the protection layer 106. In other words, at least a portion of the protection layer 106 may be uncovered. Illustratively, the exposed portion may be configured to be electrical contacted, e.g. by bonding or soldering (see FIG. 6A or FIG. 6B).

FIG. 7B illustrates a semiconductor device 700b according to various embodiments in a method according to various embodiments in a schematic side view or a schematic cross-sectional view. The semiconductor device 700b may include an electrically insulating layer 704 disposed or formed at least one of in or over the substrate 102 (e.g. being a semiconductor substrate 102). According to various embodiments, the underlying metallization layer 104, 108 is disposed or formed at least partially in the electrically insulating layer 704. In other words, at least a portion of the underlying metallization layer 104, 108 may extend into the electrically insulating layer 704, e.g. in a recess formed in the electrically insulating layer 704. The electrically insulating layer 704 may include or be formed from at least one of a dielectric material (e.g. a low-K dielectric material), e.g. a semiconductor carbide (e.g. silicon carbide (SiC)), a semiconductor oxide (e.g. silicon oxide (SiO₂)), a semiconductor nitride (e.g. silicon nitride (SiN)) and a semiconductor oxycarbide (e.g. silicon oxycarbide (SiOC)).

Illustratively, the electrically insulating layer 704 may include or be formed from a bather layer. Alternatively or additionally, the electrically insulating layer 704 may include or be formed from a etch stop layer. Alternatively or additionally, the electrically insulating layer 704 may include or be formed from a spacing layer. For example, the underlying metallization layer 104, 108 may include or be formed from at least one of a redistribution layer and a contact pad.

Optionally, the protection layer 106 may be at least partially exposed. Optionally, the underlying metallization layer 104, 108 may be at least partially exposed. Alternatively, the underlying metallization layer 104, 108 may be completely covered, e.g. by at least one of the protection layer 106 and the electrically insulating layer 704.

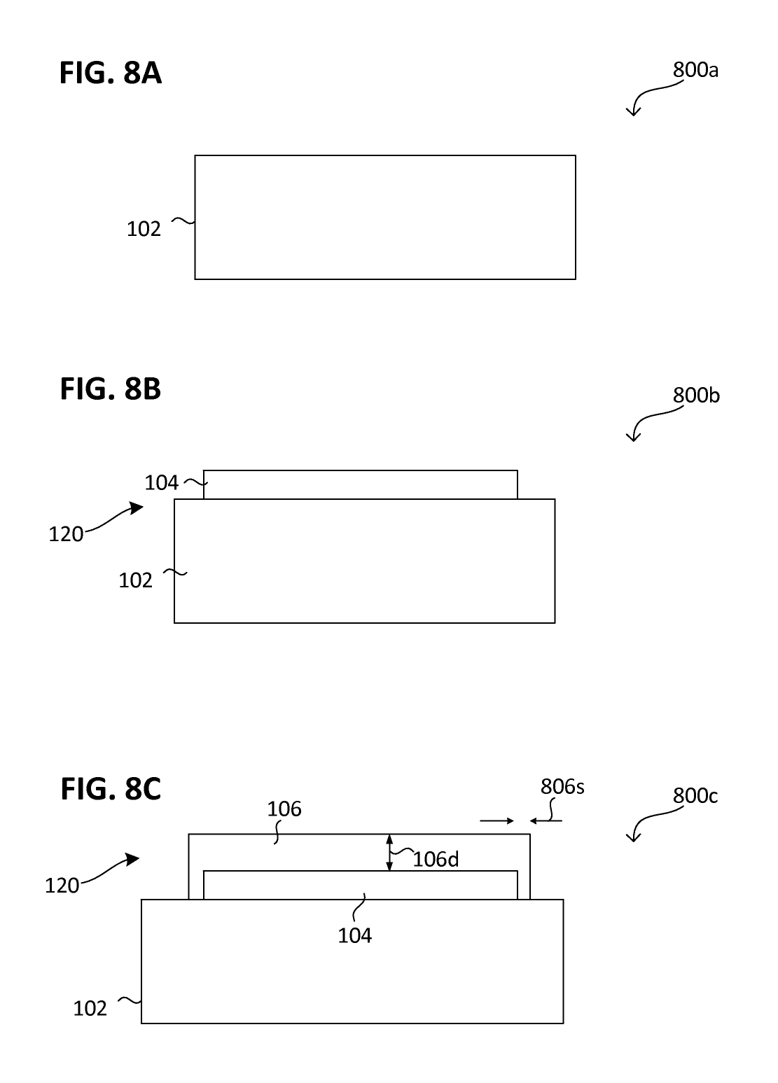

FIG. 8A, FIG. 8B and FIG. 8C respectively illustrate a semiconductor device according to various embodiments in a method according to various embodiments in a schematic side view or a schematic cross-sectional view.

As illustrated in FIG. 8A, the method may include in 800a providing a substrate 102, e.g. a semiconductor substrate 102. As illustrated in FIG. 8B, the method may include in 800b forming a metallization layer 104 (also referred to as first metallization layer 104) at least partially in or over the substrate 102. Alternatively to the in FIG. 8B illustrated geometry, forming a metallization layer 104 may result in another geometry, as described herein (see for example FIG. 1A, FIG. 1B, FIG. 2A, FIG. 2B). Forming the metallization layer 104 may include depositing a metal (also referred to as first metal) or a metal alloy (also referred to as first metal alloy) at least partially in or over the substrate 102, e.g. by at least one of physical vapor deposition (PVD), such as sputtering (e.g. magnetron sputtering, e.g. reactive magnetron sputtering) or such as electron beam deposition; chemical vapor deposition (CVD) such as ALD; electrodeposition such as plating (e.g. electroplating).

As illustrated in FIG. 8C, the method may include in 800c forming a protection layer 106 at least partially over the metallization layer 104. Forming the protection layer 106 may include depositing a nitride material, e.g. a nitride of the first metal, at least partially over the substrate 102, e.g. least partially over the metallization layer 104, e.g. e.g. by at least one of PVD; CVD such as ALD; electrodeposition.

For example (e.g. in the case of PVD), for forming the protection layer 106 a metal, e.g. the first metal, may be vaporized (e.g. by sputtering) from a target including or formed from the metal. Further, nitrogen may be added to the vaporized first metal, e.g. in gaseous form. The nitride material may be formed by a chemical reaction between the metal and nitrogen. Alternatively or additionally, nitrogen ions may be added into the deposition process. For example, the protection layer 106 may be irradiated using a nitrogen ion beam, including a nitrogen ion current.

Forming the protection layer 106 may include covering at least one of a vertical side (e.g. a front side) of the metallization layer 104 and a lateral side of the metallization layer 104. For example, the vertical side may be disposed opposite the substrate 102 and the lateral side may extend at least partially from the vertical side to the substrate 102. Optionally, the method may include removing an oxide (e.g. a metal oxide) from the metallization layer 104, e.g. prior to forming the protection layer 106.

Alternatively to the in FIG. 8C illustrated geometry, forming the protection layer 106 may result in another geometry, as described herein (see for example FIG. 1A, FIG. 1B, FIG. 2A, FIG. 2B). If a further metallization layer 108 is formed, the method may optionally include forming a protection layer 106 at least partially over the further metallization layer 108, analog to forming a protection layer 106 at least partially over the metallization layer 104. Optionally, the method may include removing an oxide from the further metallization layer 108 prior forming the protection layer 106.

Removing material may include etching or ablating a material, a layer, a region or the like. The term “etching” may include various etching procedures, e.g. chemical etching (e.g. wet etching or dry etching), physical etching, plasma etching, ion etching etc. For etching an etchant may be applied to the layer, the material or the region which is designated to be removed. The etchant may react with the layer, the material or the region forming a substance (or chemical compound) which may be easily removed, e.g. a volatile substance. Alternatively or additionally, the etchant may for example, atomize a material, a layer, a region or the like which is designated to be removed.

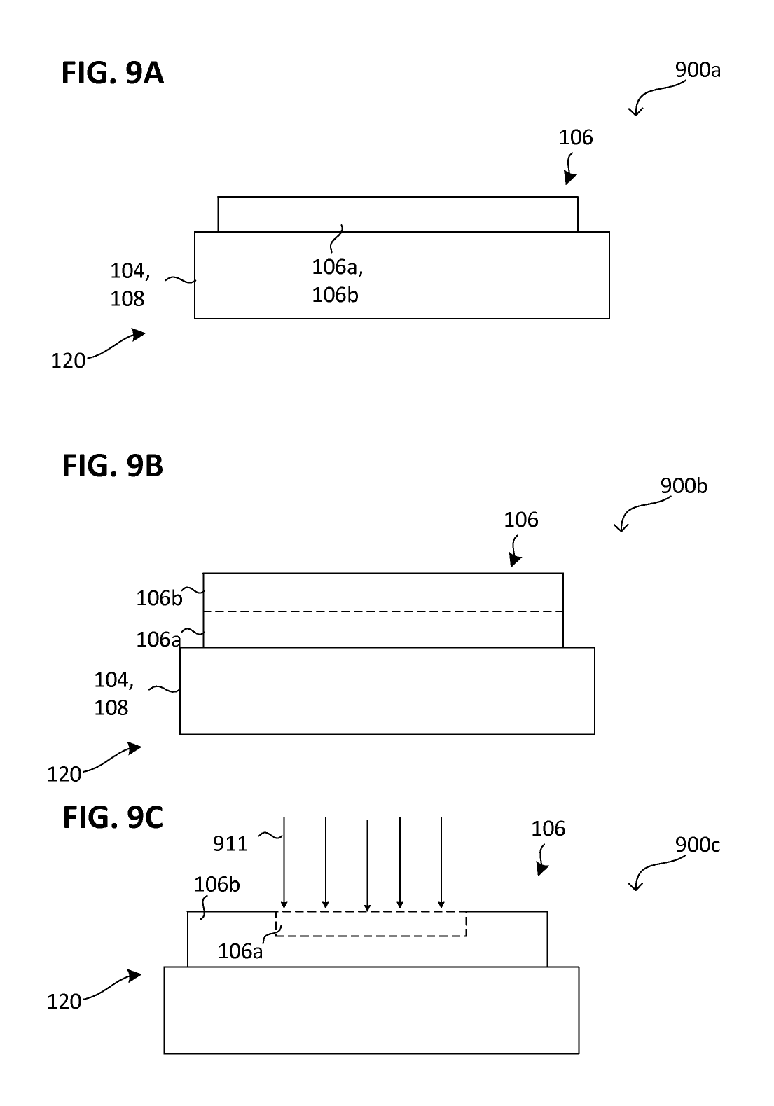

FIG. 9A, FIG. 9B and FIG. 9C respectively illustrate a semiconductor device according to various embodiments in a method according to various embodiments in a schematic side view or a schematic cross-sectional view. The method may in 900a, 900b and 900c include adjusting a composition of the protection layer 106.

Adjusting the composition of the protection layer 106 may be in accordance with a predetermined composition (e.g. a nitrogen concentration or an atomic ratio of the metal to nitrogen, respectively). Alternatively or additionally, adjusting the composition of the protection layer 106 may be in accordance with a predetermined spatial distribution of the composition (e.g. a spatially averaged nitrogen concentration or a spatially averaged atomic ratio of the metal to nitrogen, respectively). Alternatively or additionally, adjusting the composition of the protection layer 106 may be in accordance with an electrical conductivity (also referred as to an electrical conduction type), e.g. in accordance with an electrically conducting behavior or an electrically semiconducting behavior.

The method may in 900a include adjusting the composition by adjusting a process parameter for forming the protection layer 106. The process parameter may include at least one of the following: a gas flow (e.g. a nitrogen gas flow), a gas partial pressure (a nitrogen partial pressure), a temperature (e.g. a temperature of the substrate 102); a deposition rate (e.g. a deposition rate of the metal or a deposition rate of the nitride material), a ion current density (e.g. a nitrogen ion current density); a target-substrate distance (also referred to as deposition distance).

Adjusting the process parameter may include setting the process parameter to a predetermined value during forming the protection layer 106, e.g. during forming of at least one of a first region 106a and forming a second region 106b.

The method may in 900a include forming a protection layer 106 at least including an electrically conductive region. Therefore, a first region 106a may be formed, the first region 106a may include a composition in accordance with a first conduction type (e.g. electrically conducting behavior). For example, the first region 106a may be formed from a nitride material having a nitrogen concentration less than about 20 at. %. Therefore, at least one of a nitrogen gas flow and a nitrogen partial pressure in accordance with the first conduction type may be used for forming the first region 106a, e.g. in the case of reactive magnetron sputtering. Illustratively, at least one of the nitrogen gas flow and the nitrogen partial pressure may be set to a low value for forming the first region 106a.

Alternatively, the method may in 900a include to form a protection layer 106 at least including an electrically semiconducting region. Therefore, a second region 106b may be formed, the second region 106b may include a composition in accordance with a second conduction type (e.g. electrically semiconducting behavior). For example, the second region 106b may be formed from a nitride material having a concentration of nitrogen greater than about 20 at. % and alternatively or additionally less or equal to 25 at. % (e.g. in a range from about 20 at. % to about 25 at. %). Therefore, at least one of a nitrogen gas flow and a nitrogen partial pressure in accordance with the second conduction type may be used for forming the second region 106b, e.g. in the case of reactive magnetron sputtering. The second conduction type may be different from the first conduction type. Illustratively, at least one of the nitrogen gas flow and the nitrogen partial pressure may be set to a high value for forming the second region 106b.

According to various embodiments, the second region 106b may be formed at least partially over the first region 106a, resulting in a layer stack as illustrated in FIG. 9B. In this case, the first region 106a may be formed in physical contact with the underlying metallization layer 104, 108. Alternatively, the second region 106b may be formed at least partially between the first region 106a and the underlying metallization layer 104, 108, resulting in a layer stack as illustrated in FIG. 9C.

Further modifications of the method may be described with reference to FIG. 9B and FIG. 9C.

The method may optionally in 900b include adjusting the composition of the protection layer 106 by changing a process parameter during forming the protection layer. Illustratively, the process parameter may cause a transition of the deposited nitride material between semiconducting behavior and conducting behavior, e.g. during forming the protection layer 106. As illustrated in FIG. 9B, a second region 106b may be formed over the first region 106a, the second region 106b may include a composition in accordance with the second conduction type (e.g. electrically semiconducting behavior), e.g. different from a composition of the first region 106a which is in accordance with the first conduction type (e.g. electrically conducting behavior). Alternatively (not illustrated), the first region 106a may be formed over the second region 106b.

For example, adjusting the composition of the protection layer 106 may include changing (e.g. stepwise or continuously) at least one of a gas flow (e.g. a nitrogen gas flow) and a gas partial pressure (a nitrogen partial pressure). For forming the second region 106b over the first region 106a at least one of the nitrogen gas flow and the nitrogen partial pressure may be increased, e.g. during forming the protection layer 106.

Alternatively or additionally, adjusting the composition of the protection layer 106 may include changing (e.g. stepwise or continuously) the temperature of the semiconductor substrate 102 during the formation of the protection layer 106, e.g. increasing a temperature. The higher the temperature, the lower the nitrogen concentration will be. For example, the temperature may have a value greater than or equal to about 100° C. and alternatively or additionally less or equal to about 1000° C., e.g. greater than or equal to about 150° C., greater than or equal to about 200° C., greater than or equal to about 250° C., greater than or equal to about 300° C.

The method may optionally in 900c include adjusting the composition of the protection layer 106 by heating at least a portion of the protection layer 106 (also referred to as heating step), e.g. during forming the protection layer and/or after forming the protection layer. For example, the composition of the protection layer 106 may be adjusted by transforming an electrically semiconducting region at least partially, that means at least a portion (in other words, partially or completely), into an electrically conducting region. Therefore, at least a portion of the protection layer 106 (see FIG. 9A), e.g. of the second region 106b (which may be electrically semiconducting), may be transformed into an electrically conducting region. Therefore, at least a portion of the protection layer 106 may be heated to adjust the composition in accordance with the desired conduction type (e.g. electrically conducting behavior), e.g. for reducing the nitrogen concentration of the heated portion, e.g. such that a concentration of nitrogen in the portion (after heating) is in accordance with the desired conduction type, e.g. less than about 20 at. %.

Optionally, the protection layer 106 may substantially completely be transformed into an electrically conductive region, resulting in a layer stack as illustrated in FIG. 9A. Alternatively, the protection layer 106 may partially be transformed into an electrically conductive region, e.g. in the first region 106a, e.g. resulting in a layer stack as illustrated in FIG. 9B or FIG. 9C.

The method may in 900c include heating at least a portion of the protection layer 106, e.g. heating the protection layer 106 locally, to a temperature greater than or equal to about 100° C. and alternatively or additionally less or equal to about 1000° C., e.g. greater than or equal to about 150° C., greater than or equal to about 200° C., greater than or equal to about 250° C., greater than or equal to about 300° C. For example, a portion of the protection layer 106 may be heated, e.g. by irradiation 911 (illustrated by arrows) with light (e.g. using a laser source) or by irradiation 911 with an electron beam (e.g. using an electron beam source) or another irradiation (using another irradiation source), e.g. to form an electrically conducting region (e.g. in the first region 106a).

A composition of the heated region, e.g. the first region 106a, may be changed (e.g. by heating), e.g. a concentration of nitrogen of the heated region may be reduced. For example, the electrical conductivity of the heated region may be changed, e.g. increased (by heating). In other words, adjusting the composition of the protection layer 106 may in 900c include adjusting a composition of a region (e.g. at least the first region 106a) of the protection layer 106 in accordance with electrically conducting behavior.

Alternatively or additionally, the method may in 900c include adjusting a composition of at least a region of the protection layer 106 in accordance with electrically semiconducting behavior. Therefore, the method may in 900c include to expose a region (e.g. the second region 106b) of the protection layer 106 to a nitrogen reactant, e.g. a reactive nitrogen atmosphere (e.g. a plasma including nitrogen), or a nitrogen ion beam. For example, a composition of the exposed region of the protection layer 106, e.g. the second region 106b, may be changed, e.g. a concentration of nitrogen may be increased. For example, the electrical conductivity of the exposed region may be changed, e.g. reduced (by exposing).

According to various embodiments, nitrogen may be transferred out of the first region 106a of the protection layer 106 by heating the first region 106a of the protection layer 106 and nitrogen may be transferred into the second region 106b of the protection layer 106 by exposing the second region 106b of the protection layer 106 to a nitrogen reactant.

The method may in 900b and/or 900c optionally include forming a respective composition being spatially substantially constant within at least one of the first region 106a and the second region 106b. Alternatively or additionally, the method may in 900b and/or 900c include forming a respective composition gradient profile (e.g. at least one of a nitrogen concentration gradient profile and an atomic ratio gradient profile) in the protection layer 106. The composition gradient profile may at least range from the composition of the first region 106a to the composition of the second region 106b.

Illustratively, the physical properties of the protecting layer 106 may be adjusted according to certain requirements by a heating step, e.g. before wire bonding, e.g. during a back end process (BE). For example, adjusting the composition of the protection layer may provide a highly conductive protection layer 106 (or at least a highly conductive first region 106a of the protection layer 106), e.g. for electrical contacting the protection layer 106.

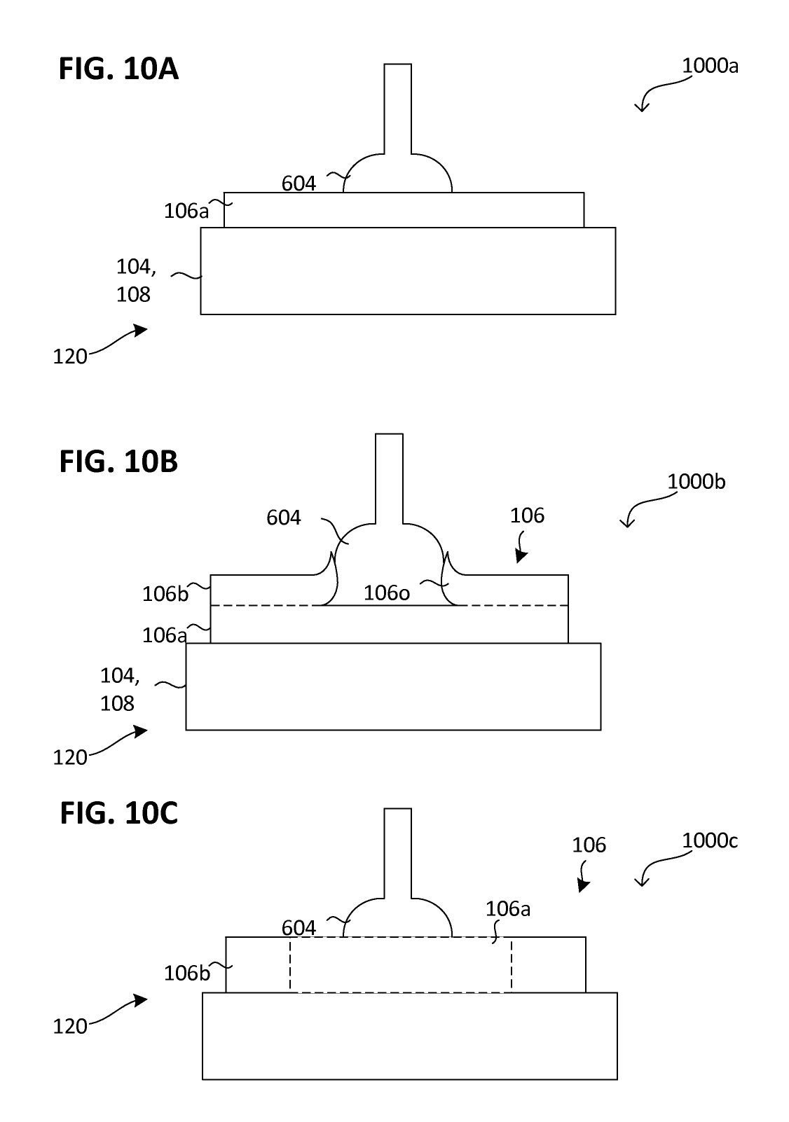

FIG. 10A, FIG. 10B and FIG. 10C respectively illustrate a semiconductor device according to various embodiments in a method according to various embodiments in a schematic side view or a schematic cross-sectional view. The method may in 1000a, 1000b and 1000c include electrically contacting a metallization layer 104,108 (e.g. at least one of the first metallization layer 104 and the second metallization layer 108).

As illustrated in FIG. 10A, the method may include in 1000a forming a bonding joint 604 over the metallization layer 104, 108, e.g. over the protection layer 106, e.g. over a first region 106a of the protection layer 106. The first region 106a may be an electrically conducting (in other words the first region 106a may be an electrically conducting region). Illustratively, this may establish an electrical connection between the bonding joint 604 and the metallization layer 104,108 with low ohmic resistance.

For example, a copper nitride (CuₓN_{y}) protection layer 106 (e.g. including a thickness 106d less than 40 nm) may be used for protecting a metal surface, e.g. a Cu surface. The protection layer 106 may be deposited by reactive magnetron sputtering and may be configured to be bondable (e.g. the protection layer may be electrically conductive for wire bonding).

As illustrated in FIG. 10B, the method may include in 1000b opening the protection layer 106 at least partially, e.g. at least the second region 106b. In other words an opening 106o may be formed in the protection layer 106. The opening may extend at least partially through the protection layer 106, e.g. at least through the second region 106b (which e.g. may be a semiconducting region). In this case, the bonding joint 604 may contact the first region 106a (which e.g. may be a conducting region). Alternatively, the opening 106o may extend completely through the protection layer 106 (see e.g. FIG. 6C).

Illustratively, the protection layer 106, or at least a semiconducting region, may be configured to be thin enough to crack at a bonding procedure, e.g. due to the corresponding mechanical load applied by bonding. By adjusting the thickness 106d of the protection layer 106, e.g. at least the thickness of a semiconducting region of the protection layer 106, the protection layer 106 may be broken at least partially by wire bonding to have a highly conductive wire-to-metallization-connection (e.g. a Cu-wire to Cu-metallization interface for the interconnects). In this case, the protection layer 106 may protect the remaining metallization layer 104, 108 (e.g. its surface) even after extended moisture soak at higher temperatures, e.g. during at least one of a front end of line (FEOL) process and a back end of line (BEOL) process.

As illustrated in FIG. 10C, the method may include in 1000b electrically contacting a first region 106 of the protection layer 106 (which e.g. may be a conducting region). The first region 106 may extend through the protection layer 106 and may be at least partially surrounded by the second region 106b (which e.g. may be a semiconducting region). In other words, the first region 106 of the protection layer 106 may be in physical contact to the bonding joint 604 and the metallization layer 104,108. Illustratively, the first region 106 of the protection layer 106 may include or be formed from a bonding region. For example, a concentration of N in the first region 106a may be configured (illustratively be low enough) for wire bonding.

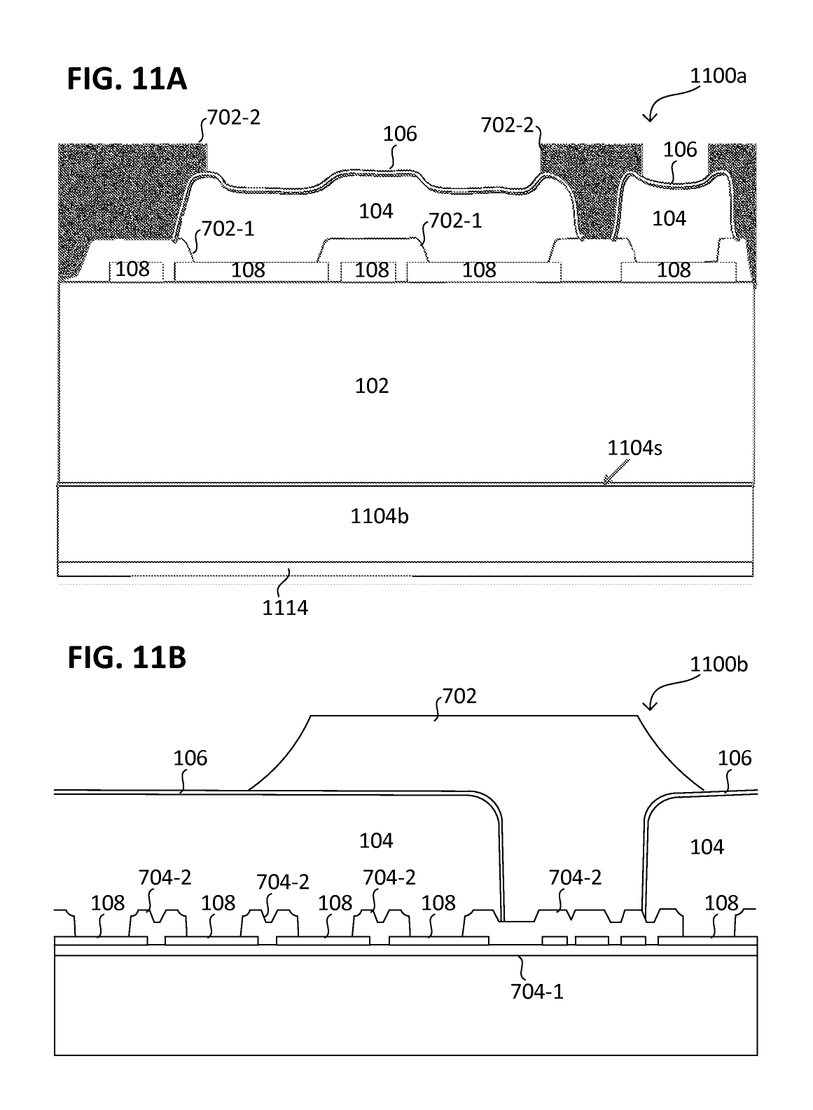

FIG. 11A illustrates a semiconductor device 1100a according to various embodiments in a method according to various embodiments in a schematic side view or a schematic cross-sectional view. The semiconductor device 1100a may include a substrate 102, e.g. a semiconductor substrate 102, a back side metallization layer 1104b, a first metallization layer 104, a second metallization layer 108, a first polymer layer 702-1, a second polymer layer 702-2 and at least one protection layer 106. The first polymer layer 702-1 may include or be formed from an imide, e.g. a polyimide. The second polymer layer 702-2 may include or be formed from a resin, e.g. an epoxy resin.

The second metallization layer 108 may be disposed or formed at least partially between the substrate 102 and the first metallization layer 104. The first polymer layer 702-1 may be disposed or formed at least partially between the first metallization layer 104 and the second metallization layer 108. The first polymer layer 702-1 may be formed or disposed at least partially over the substrate 102 and at least partially over the second metallization layer 108. The second polymer layer 702-2 may be disposed or formed at least partially over the first polymer layer 702-1 and at least partially over the first metallization layer 104. The second polymer layer 702-1 may be formed over the substrate 102 and at least partially over the second metallization layer 108.

The semiconductor device 1100a may optionally include at least one of a back side metallization seed layer 1104s and a back side coating layer 1114. The back side metallization seed layer 1104s may be formed between the substrate 102 and the back side metallization layer 1104b. The back side metallization seed layer 1104s may be formed prior the back side metallization layer 1104b. The back side metallization layer 1104b may include or be formed from a back side contact pad. For example, the back side metallization layer 1104b may be electrically connected to an electrically conductive region of a circuit component, e.g. to a drain region. The back side coating layer 1114 may be formed under the back side metallization layer 1104b and may include or be formed from a metal, e.g. Ag or Sn. The back side coating layer 1114 may provide at least one of a bondable and solderable surface.

The first polymer layer 702-1 may include a thickness less than a thickness of the second polymer layer 702-2. For example, the first polymer layer 702-1 may include a thickness in the range from about 1 μm to about 10 μm, e.g. in the range from about 2 μm to about 6 μm e.g. about 5 μm. For example, the second polymer layer 702-2 may include a thickness in the range from about 5 μm to about 50 μm, e.g. in the range from about 10 μm to about 20 μm.

The first metallization layer 104 may include a thickness less than a thickness of the second metallization layer 108. For example, the first metallization layer 104 may include a thickness in the range from about 5 μm to about 20 μm, e.g. in the range from about 8 μm to about 15 μm, e.g. about 10 μm. For example, the second metallization layer 108 may include a thickness in the range from about 0.1 μm to about 5 μm, e.g. in the range from about 1 μm to about 3 μm. The thickness of the second metallization layer 108 may be less than the thickness of the first polymer layer 702-1.

The substrate 102, e.g. a semiconductor substrate 102, may include a thickness in the range from about 10 μm to about 200 μm, e.g. in the range from about 20 μm to about 100 μm, e.g. about 50 μm. The back side metallization layer 1104b may include a thickness in the range from about 1 μm to about 50 μm, e.g. in the range from about 5 μm to about 20 μm, e.g. about 10 μm. The back side coating layer 1114 may include a thickness less than the thickness of the back side metallization layer 1104b

As illustrated in FIG. 11A, the first metallization layer 104 may include or be formed from a final metallization, e.g. including or formed from one or more contact pads, e.g. bonding pads. The second metallization layer may include or be formed from an interlayer metallization, e.g. including or formed from one or more interconnection pads, which are electrically connected to one or more circuit components, e.g. to at least one of the following: a source region of a circuit component, a drain region of a circuit component, a gate region of a circuit component. Regarding to the electrical connection, the interconnection pads may also be referred as gate pad, drain pad or source pad. For example, the first metallization layer 104 may be formed from Cu.

According to various embodiments, the second metallization layer 108 may include or be formed from a metal alloy which includes or is formed from the second metal alloy including the second metal and optionally at least one of another metal and Si. For example, the second metal alloy may include or be formed from Cu and Al, e.g. in form of a CuAl alloy. Alternatively, the second metal alloy may include or be formed from Si and Al, e.g. in form of an AlSi alloy.

FIG. 11B illustrates a semiconductor device 1100b according to various embodiments in a method according to various embodiments in a schematic side view or a schematic cross-sectional view. The semiconductor device 1100b may include a first electrically insulating layer 704-1, a second electrically insulating layer 704-2, a first metallization layer 104, a second metallization layer 108, a polymer layer 702 and at least one protection layer 106.

The first electrically insulating layer 704-1 may include or be formed from an oxide, e.g. a semiconductor oxide. In this case, the first electrically insulating layer 704-1 may also be referred as to an oxide interlayer. Electrically conducting layers (e.g. metallization layers) on both sides of the first electrically insulating layer 704-1 may be electrically connected by an electrical connection (interlayer connection, also referred to as via) which extends through (not shown) the first electrically insulating layer 704-1. The first electrically insulating layer 704-1 may include a thickness less than a thickness of at least one of the first metallization layer 104, the polymer layer 702 and the second electrically insulating layer 704-2. For example, the first electrically insulating layer 704-1 may include a thickness in the range from about 100 nm to about 5 μm, e.g. in the range from about 300 nm to about 1 μm, e.g. about 600 nm.

The second electrically insulating layer 704-2 may include or be formed from at least one of a semiconductor oxide and a semiconductor nitride (e.g. SiN). In this case, the second electrically insulating layer 704-2 may at least partially be formed using a high density plasma process. The second electrically insulating layer 704-2 may include a thickness less than a thickness of at least one of the first metallization layer 104 and the polymer layer 702. For example, the second electrically insulating layer 704-2 may include a thickness in the range from about 100 nm to about 5 μm, e.g. in the range from about 1 μm to about 2 μm, e.g. about 1.6 μm.

Optionally, the second metallization layer 108 may include more than one electrically conductive layer, e.g. at least two of: a metal alloy layer (e.g. including the first metal, e.g. an AlCu alloy), a metal layer (e.g. a Ti layer), a nitride layer (e.g. TiN).

The polymer layer 702 may include or be formed from an imide, e.g. a polyimide, including a thickness in the range from about 5 μm to about 100 μm, e.g. in the range from about 10 μm to about 50 μm, e.g. about 32 μm. The first metallization layer 104 may include or be formed from the first metal, e.g. Cu, including a thickness in the range from about 1 μm to about 50 μm, e.g. in the range from about 10 μm to about 20 μm, e.g. about 20 μm.

The protection layer 106 may cover a vertical side (e.g. a front side) of the first metallization layer 104 at least partially and a lateral side of the first metallization layer 104 at least partially. In this case, the protection layer 106 may replace a conventional adhesion layer passivation, e.g. covering at least a portion of the first metallization layer 104. Alternatively, the protection layer 106 may cover the first metallization layer 104 completely.

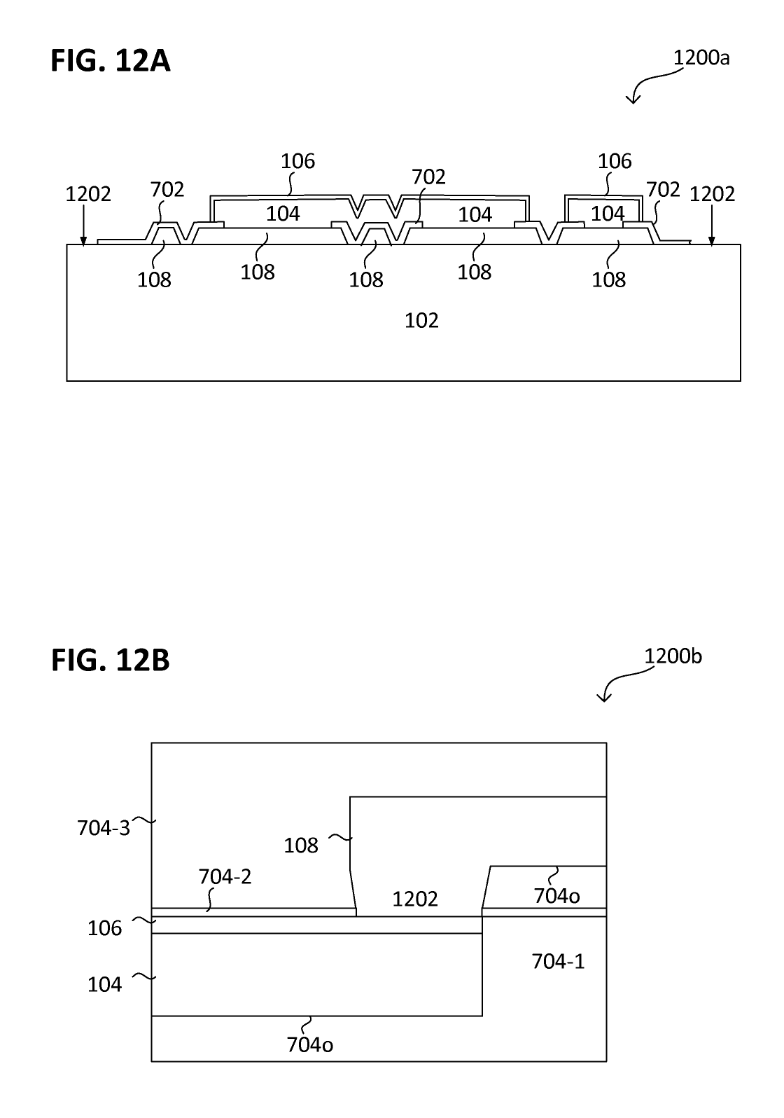

FIG. 12A illustrates a semiconductor device 1200a according to various embodiments in a method according to various embodiments in a schematic side view or a schematic cross-sectional view. The semiconductor device 1200a may include a semiconductor substrate 102, a first metallization layer 104, a second metallization layer 108, a polymer layer 702, and at least one protection layer 106. The polymer layer 702 may include or be formed from an imide, e.g. a polyimide. The semiconductor device 1200a may be formed similar to the semiconductor device 1100a.

The semiconductor device 1200a may optionally include a kerf region 1202. The kerf region 1202 may define a path along which the semiconductor substrate 102 is designated to be cut, e.g. sawed, milled, diced, etc., on order to singulate the semiconductor device 1200a from the semiconductor substrate 102.

FIG. 12B illustrates a semiconductor device 1200b according to various embodiments in a method according to various embodiments in a schematic side view or a schematic cross-sectional view. The semiconductor device 1200b may include a first electrically insulating layer 704-1, a second electrically insulating layer 704-2, a third electrically insulating layer 704-3, a first metallization layer 104, a second metallization layer 108, and at least one protection layer 106.

The first electrically insulating layer 704-1 and the third electrically insulating layer 704-3, respectively, may include or be formed from an oxide, e.g. a semiconductor oxide (e.g. being configured as an oxide interlayer). The second electrically insulating layer 704-2 may include or be formed from a semiconductor nitride, e.g. SiN. The second electrically insulating layer 704-2 may include or be formed from at least one of a bather layer and an etch stop layer. At least one of the first electrically insulating layer 704-1 and the third electrically insulating layer 704-3 may optionally further include at least one of one or more bather layers and one or more etch stop layers (not shown), e.g. similar to the second electrically insulating layer 704-2.

The first metallization layer 104 and the second metallization layer 108 may include or be formed from a redistribution layer. A part of the second metallization layer 108 may be formed as interlayer connection, which extends through an opening in the second electrically insulating layer 704-2. The first metallization layer 104 and the second metallization layer 108 may be coupled with each other, e.g. electrically connected to each other. The first metallization layer 104 may at least be partially disposed or formed in the first electrically insulating layer 704-1. The second metallization layer 108 may at least be partially disposed or formed in the second electrically insulating layer 704-2. Therefore, the first electrically insulating layer 704-1 may include an opening 704o formed prior forming the first metallization layer 104. Alternatively or additionally, the third electrically insulating layer 704-3 may include an opening 704o formed prior forming the second metallization layer 108.

At least one of the first metallization layer 104 and the second metallization layer 108 may include or be formed from Cu or various metal alloys including Cu (Cu-alloy, e.g. Cu based), optionally including Mg, Zn, zirconium (Zr), Sn, nickel (Ni), or palladium (Pd). Forming at least one of the first metallization layer 104 and the second metallization layer 108 may include depositing Cu or a Cu alloy using electroplating. Therefore, a seed layer (not shown) may be formed on the corresponding electrically insulation layer, at least partially in the opening 704o of the corresponding electrically insulation layer, e.g. lining the opening 704o. The seed layer may provide enhanced nucleation and adhesion of the electroplated Cu or Cu-alloy. The seed layer may include a Cu-alloy optionally including alloying elements such as Mg, Al, Zn, Zr, Sn, Ni, Pd, Ag, or Au. The seed layer may be formed using a sputter deposition or using CVD. At least one of the first metallization layer 104 and the second metallization layer 108 may be formed or disposed in the corresponding opening 704o.

At least one the first metallization layer 104, the second metallization layer 108 and the protection layer 106 may be disposed or formed similar to the layer arrangement 120, e.g. as illustrated in FIG. 2A and/or FIG. 7B.

According to various alternative embodiments, the semiconductor device 1200a may not include the second electrically insulating layer 704-2.

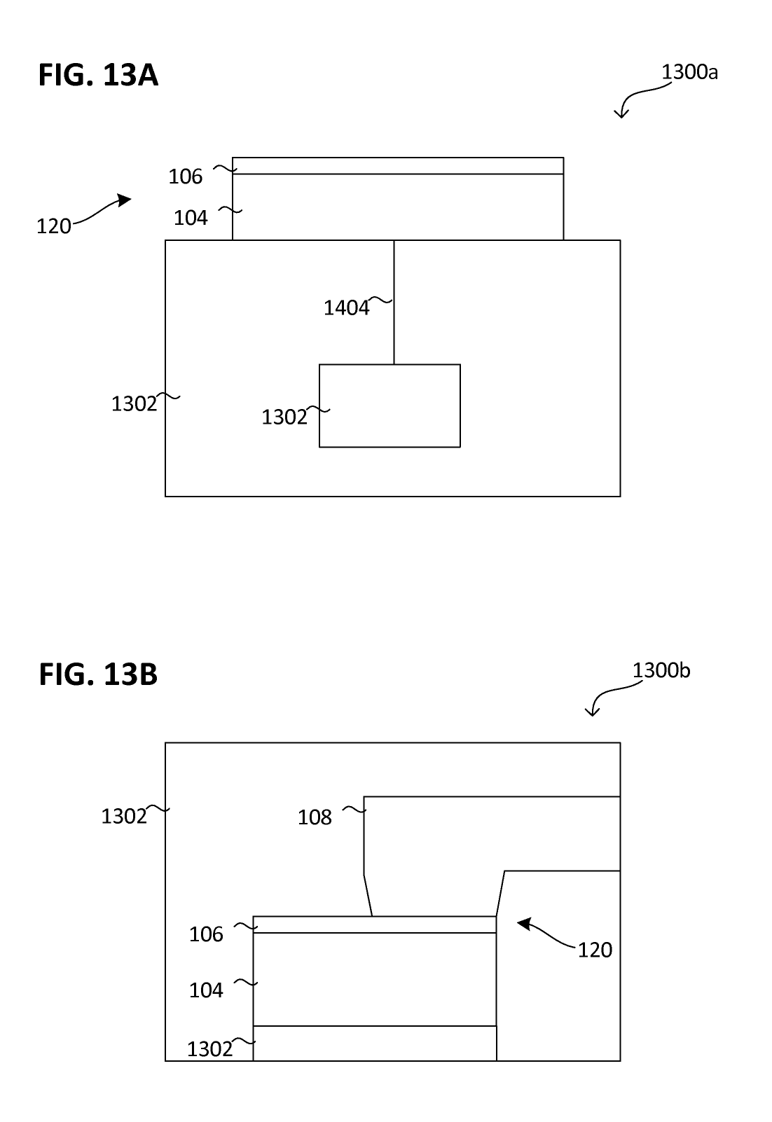

FIG. 13A illustrates a semiconductor device 1300a according to various embodiments in a method according to various embodiments in a schematic side view or a schematic cross-sectional view, e.g. similar to a configuration as described herein (see e.g. FIG. 1A, FIG. 1B, FIG. 2A, FIG. 2B).

The semiconductor device 1300a may include a substrate 1302. The substrate 1302 may include or be formed from at least one of a semiconductor substrate and an electrically isolation layer. The semiconductor device 1300a may further include an electrically conductive region 1302, which may be part of a circuit component. The electrically conductive region 1302 may be formed in or over the substrate 1302, e.g. in or over the semiconductor substrate. As illustrated in FIG. 13A, the semiconductor device 1300a may further include a protection layer 106 and the first metallization layer 104. The first metallization layer 104 may be electrically connected to the electrically conductive region 1302, e.g. by an electrical interconnection which may include or be formed from at least one of the following: a redistribution layer, an interlayer connection, an interlayer metallization.

FIG. 13B illustrates a semiconductor device 1300b according to various embodiments in a method according to various embodiments in a schematic side view or a schematic cross-sectional view, e.g. similar to a configuration as described herein (see e.g. FIG. 1A, FIG. 1B, FIG. 2A, FIG. 2B, FIG. 13A, FIG. 12B).

As illustrated in FIG. 13B, the semiconductor device 1300b may include a protection layer 106, the first metallization layer 104 and the second metallization layer 108, which may be formed at least partially over the electrically conductive region 1302. The first metallization layer 104 may be electrically connected to the electrically conductive region 1302, e.g. in physical contact.

The first metallization layer 104 and the second metallization layer 108 may be formed at least partially in the substrate 1302, which may include or be formed from at least one of the semiconductor substrate and one or more electrically insulating layers. The second metallization layer 108 may include or be formed from a redistribution layer and may be part of an electrical interconnection.

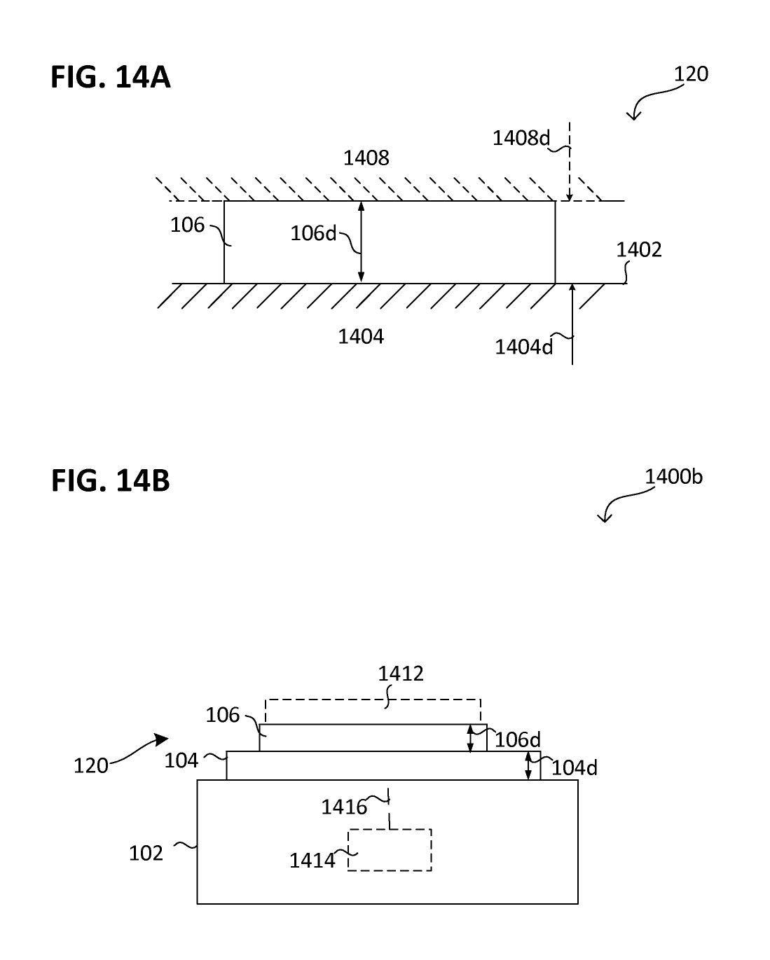

FIG. 14A illustrates a layer arrangement 120 according to various embodiments in a method according to various embodiments in a schematic side view or a schematic cross-sectional view.

According to various embodiments, the layer arrangement 120 may include a first layer 1404 including a metallic surface 1402. The metallic surface 1402 may include or be formed from a metal, e.g. at least one metal of the following metals: copper, aluminum, gold, and silver. The first layer 1404 may include or be formed from at least one metallic layer, e.g. at least one of a first metallization layer 104 and a second metallization layer 108. The at least one metallic layer may optionally be formed over at least one of an insulating material and a semiconducting material.

The layer arrangement 120 may further include a protection layer 106. The protection layer 106 may include or be formed from CuₓN_{y} and may be formed at least partially over the metallic surface. The sum of x and y may be equal to 1. Alternatively or additionally, the ratio x/y may define an atomic ratio of Cu to N. Optionally, the layer arrangement 120 may include a second layer 1408 formed at least partially over the protection layer 106. The second layer may include or be formed from at least one of the following: a metallic layer (e.g. at least one of a first metallization layer 104 and a second metallization layer 108), an electrically insulation layer, a polymer layer, a supporting material layer (e.g. being part of a package). The supporting material layer may include or be formed from a mold material, e.g. a mold compound.

For example, the second layer 1408 may include or be formed from at least one of the following: an electrical contact; a passivation; a bather; a package; a metallization.

The second layer 1408 may include or be formed from an electrically conductive material, e.g. at least one of: a metal, solder material, a bonding material, the first metal, the second metal, a metal alloy. Alternatively or additionally, the second layer 1408 may include or be formed from an electrically insulating material, e.g. at least one of: an oxide, a semiconductor nitride, a polymer, a mold material. Alternatively or additionally, the layer 1408 may include or be formed from a semiconducting material. Alternatively, the layer 1408 may include or be formed from at least one of: the second metallization layer 108, an electrically insulating layer (e.g. the second electrically insulating layer 704-2 or the third electrically insulating layer 704-3), a polymer layer (e.g. the first polymer layer 702-1 or the second polymer layer 702-2).

In case that the layer 1408 includes a mold material, the layer 1408 may be part of a package (e.g. an integrated circuit package) which may at least partially surround at least one of the substrate 102, the first metallization layer 104 and the protection layer 106. In other words, at least one of the substrate 102, the first metallization layer 104 and the protection layer 106 may be at least partially embedded into the mold material.

In case that the layer 1408 includes a bonding material, the layer 1408 may be part of a bonding joint 604 (see e.g. FIG. 6B). In case that the layer 1408 includes a solder material, the layer 1408 may be part of a solder joint 602 (see e.g. FIG. 6A). In case that the layer 1408 includes an electrically insulating material, the layer 1408 may be part of a passivation, e.g. a final passivation. In other words, the layer 1408 may include or be formed from a passivation layer.

According to various embodiments, a thickness 106d of the protection layer 106 may less than or equal to about 500 nm and alternatively or additionally greater than about 0.01 nm, e.g. less than or equal to about 0.4 μm, e.g. less than or equal to about 0.3 μm, e.g. less than or equal to about 0.2 μm, e.g. less than or equal to about 0.1 μm (100 nm), e.g. less than or equal to about 50 nm, e.g. less than or equal to about 40 nm, e.g. less than or equal to about 30 nm, e.g. less than or equal to about 20 nm, e.g. less than or equal to about 10 nm, e.g. less than or equal to about 5 nm.

Alternatively or additionally, a thickness of the protection layer 106 is less than or equal to a thickness 1404d of the first layer 1404, e.g. less than about 50% of the thickness 1404d of the first layer 1404, e.g. less than about 10% of the thickness 1404d of the first layer 1404, e.g. less than about 1% of the thickness 1404d of the first layer 1404, e.g. less than about 0.1% of the thickness 1404d of the first layer 1404, e.g. less than about 0.01% of the thickness 1404d of the first layer 1404.

Alternatively or additionally, a thickness of the protection layer 106 is less than or equal to a thickness 1408d of the second layer 1408, e.g. less than about 50% of the thickness 1408d of the second layer 1408, e.g. less than about 10% of the thickness 1408d of the second layer 1408, e.g. less than about 1% of the thickness 1408d of the second layer 1408, e.g. less than about 0.1% of the thickness 1408d of the second layer 1408, e.g. less than about 0.01% of the thickness 1408d of the second layer 1408.

According to various embodiments, the protection layer 106 may be configured for protecting the metallic surface 1402 from environmental influences, e.g. during forming the second layer 1408.

FIG. 14B illustrates a semiconductor device 1400b according to various embodiments in a method according to various embodiments in a schematic side view or a schematic cross-sectional view.

The semiconductor device 1400b may include a substrate 102, e.g. a semiconductor substrate 102; a first metallization layer 102 formed or disposed at least one of in or over the substrate 102; and a protection layer 106 disposed or formed at least partially over the first metallization layer 104. The protection layer may include or be formed from CuₓN_{y}. The first metallization layer 102 may include or be formed from at least one of the following: the first metal, the first metal alloy. The first metal alloy may include the first metal and optionally another metal, e.g. an alloying element.

Optionally, the semiconductor device 1400b may further include a layer 1412 formed or disposed at least partially over the protection layer 106, e.g. the second layer 1408.

Optionally, the semiconductor device 1400b may further include a circuit component 1414 integrated in the substrate 102, e.g. in a semiconductor substrate 102. Optionally, the semiconductor device 1400b may further include an electrical interconnection 1416 which may include or be formed from at least one of the following: redistribution layer, an interlayer connection, an interlayer metallization. The electrical interconnection 1416 may be electrically connect the circuit component 1414 to the first metallization layer 104.

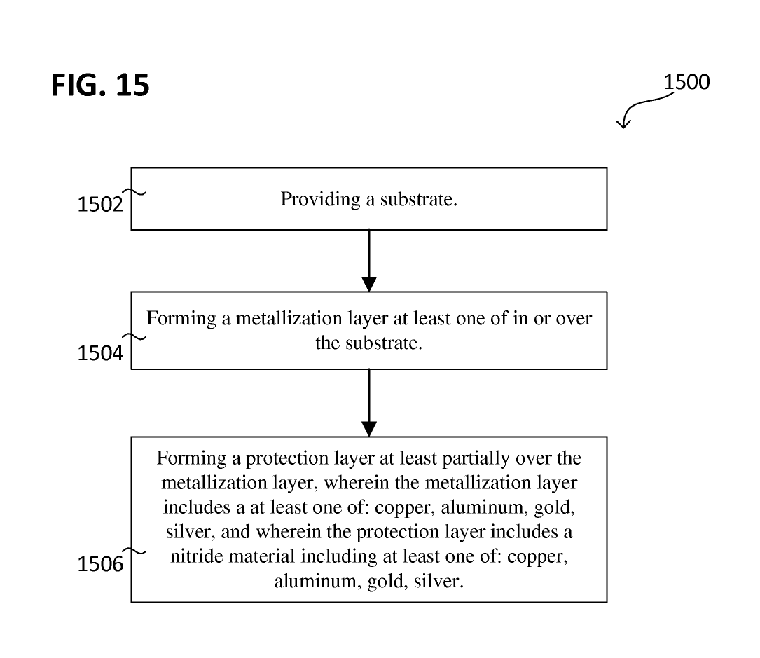

FIG. 15 illustrates a method 1500 according to various embodiments in a schematic flow diagram. The method may in 1502 include providing a substrate, e.g. a semiconductor substrate. The method may in 1504 further include forming a metallization layer at least one of in or over the substrate. The method may in 1506 further include forming a protection layer at least partially over the metallization layer, wherein the metallization layer includes a at least one of: copper, aluminum, gold, silver, and wherein the protection layer includes a nitride material including at least one of: copper, aluminum, gold, silver. The method may be further configured, as described herein.

According to various embodiments, the protection layer may include or be formed from nano crystalline (e.g. with a grain size about in a range from about 40 nm to about 60 nm) nitride material (e.g. MₓN_{y}). The protection layer may be formed (e.g. deposited) using direct current (DC) sputtering. The electrical conductivity of the protection layer may inversely proportional to the concentration of nitrogen in the protection layer. A concentration of nitrogen of about 21% (corresponding to a concentration of metal M of about 79%) of the protection layer may result in a metallic conducting protection layer with excellent electrical conductivity via a percolation mechanism, whereas a slightly substoichiometric M₃N metal alloy (wherein the metal M may be Cu) may include a typical behavior of deficit semiconductors with an optical band gap of 1.85 eV.

An artificial aging test may simulate chemical attacks to the protection layer, e.g. under conditions of about 95% humidity at about 60° C. for many months, e.g. more than 15 month. According to various embodiments, the protection layer is chemically stable enough (inert) to avoid changes in its optical characteristics during the aging test. Depending on the underlying layer (e.g. the first metallization layer) the protection layer is chemically stable even above 100° C. for many months.

According to various embodiments, the crystallite size, grain size, and surface roughness of the protection layer may be increased with temperature, e.g. during at least one of forming the protection layer and adjusting the composition of the protection layer. Further, the reactivity of the metal of the protection layer (e.g. a transition metal like Cu) with nitrogen may be increased with temperature, e.g. during at least one of forming the protection layer and during adjusting the composition of the protection layer.

According to various embodiments, at least one of the composition and the presence of the protection layer may be identified by reverse engineering the semiconductor device, e.g. focusing on at least one of a cross section and a surface of a metallization layer, e.g. of at least one of the first metallization layer and the second metallization layer. By analyzing the composition (e.g. at least one of a chemical composition, a depth profile, an atomic ratio of two chemical elements, a concentration of a chemical element, and the atomic composition) of a region at least one of over or in the metallization layer (e.g. at its surface) at least one of the composition and the presence of the protection layer may be revealed. The composition (e.g. of the protection layer) may be obtained using at least one of energy dispersive X-ray spectroscopy (EDX), transmission electron microscopy (TEM) and X-ray photoelectron spectroscopy (XPS). The depth profile may be obtained using at least one of auger electron spectroscopy (AES) and secondary ion mass spectrometry (SIMS). An EDX analysis may penetrate the whole layer thickness of the metallization layer and may therefore be used to obtain an spatially averaged composition, e.g. at least one of the spatially averaged concentration of N of the protection layer and the spatially averaged atomic ratio (e.g. of metal to nitrogen) of the protection layer, e.g. at least averaged along the vertical direction (thickness direction).

A spatially averaged composition, e.g. at least one of a spatially averaged concentration and a spatially averaged atomic ratio, of a material, a layer, a region or the like may be understood to be averaged over substantially an extension, e.g. at least one of the vertical extension (thickness) and the lateral extension, of the material, layer, region or the like, e.g. over substantially the volume of the material, layer, region or the like, e.g. over at least about 50% of the extension (or the volume, respectively) of the material, layer, region or the like, e.g. over at least about 60% of the extension (or the volume, respectively), e.g. over at least about 70% of the extension (or the volume, respectively), e.g. over at least about 80% of the extension (or the volume, respectively), e.g. over at least about 90% of the extension (or the volume, respectively), e.g. over substantially 100% of the extension (or the volume, respectively).

Further, preferred embodiments will be described in the following:

A semiconductor device may include: a substrate; a metallization layer (also referred to as first metallization layer) disposed at least one of in or over the substrate; a protection layer disposed at least partially over the metallization layer, wherein the metallization layer includes or is formed from at least one of: copper, aluminum, gold, silver; and wherein the protection layer includes or is formed from a nitride material including at least one of: copper, aluminum, gold, silver.

A semiconductor device may include: a substrate; a first metallization layer disposed at least one of in or over the substrate; a protection layer disposed at least partially over the first metallization layer, wherein the first metallization layer includes or is formed from a first metal and wherein the protection layer includes or is formed from a nitride material including the first metal.

According to various embodiments, the substrate is a semiconductor substrate, e.g. the substrate may include or be formed from silicon.

According to various embodiments, the protection layer is at least partially in physical contact with the metallization layer.

According to various embodiments, the metallization layer includes or is formed from a metal alloy including at least one of: copper, aluminum, gold, and silver.

According to various embodiments, the metallization layer includes or is formed from copper.

According to various embodiments, the protection layer includes or is formed from a nitride material including copper.

According to various embodiments, the protection layer includes or is formed from at least a first region and a second region which differ from each other by at least a chemical composition.

According to various embodiments, a concentration of nitrogen in the first region is different from a concentration of nitrogen in the second region.

According to various embodiments, a concentration of nitrogen in the first region is less than a concentration of nitrogen in the second region.

According to various embodiments, a concentration of nitrogen in the first region is equal to or less than about 20 atomic percent and a concentration of nitrogen in the second region is greater than about 20 atomic percent, e.g. the concentration of nitrogen in the second region is in the range from about 20 atomic percent to about 25 atomic percent.

According to various embodiments, an atomic ratio of a metal to nitrogen in the first region is different from an atomic ratio of the metal to nitrogen in the second region.

According to various embodiments, an atomic ratio of a metal to nitrogen in the first region is greater than an atomic ratio of the metal to nitrogen in the second region.

According to various embodiments, an atomic ratio of a metal to nitrogen in the first region is equal to or greater than about 4 and an atomic ratio of the metal to nitrogen in the second region is less than about 4.

According to various embodiments, an electrical conductivity of the first region is greater than an electrical conductivity of the second region.

According to various embodiments, the first region is electrically conducting and the second region is electrically semiconducting.

According to various embodiments, at least a portion of the second region is disposed over the first region.

According to various embodiments, the first region and the second region are disposed at least partially laterally next to each other.

According to various embodiments, the protection layer includes a composition gradient profile ranging from a first composition to a second composition.

According to various embodiments, the composition gradient profile includes a concentration gradient profile ranging from a first concentration of nitrogen to a second concentration of nitrogen.

According to various embodiments, the composition gradient profile includes an atomic ratio gradient profile ranging from a first atomic ratio of a metal to nitrogen to a second atomic ratio of the metal to nitrogen.

According to various embodiments, a concentration of nitrogen is spatially substantially constant within at least one region of the protection layer.

According to various embodiments, an atomic ratio of metal to nitrogen is spatially substantially constant within at least one region of the protection layer.

According to various embodiments, a spatial average atomic ratio of metal to nitrogen within the protection layer is equal to or greater than about 3.

According to various embodiments, a spatial average atomic ratio of metal to nitrogen within the protection layer is equal to or greater than about 4.

According to various embodiments, a spatial average atomic ratio of metal to nitrogen within the protection layer is equal to or greater than about 5.

According to various embodiments, a spatial average atomic ratio of metal to nitrogen within the protection layer is in the range from about 3 to about 20.

According to various embodiments, a spatial average concentration of nitrogen within the protection layer is equal to or less than about 25 atomic percent.

According to various embodiments, a spatial average concentration of nitrogen within the protection layer is in the range from about 5 atomic percent to about 25 atomic percent.

According to various embodiments, a spatial average concentration of nitrogen within the protection layer is equal to or less than about 20 atomic percent.

According to various embodiments, a spatial average concentration of nitrogen within the protection layer is equal to or less than about 12.5 atomic percent.

According to various embodiments, the semiconductor device may further include: a solder joint disposed at least partially over the protection layer.

According to various embodiments, the solder joint includes or is formed from at least one of: lead, tin, silver, aluminum.

According to various embodiments, the solder joint includes or is formed from a metal alloy including at least one of: lead, tin, silver, aluminum.

According to various embodiments, the semiconductor device may further include: a bonding joint disposed at least partially over the protection layer.

According to various embodiments, the bonding joint includes or is formed from at least one of: gold, aluminum, silver, and copper.

According to various embodiments, the bonding joint includes or is formed from a metal alloy including at least one of: gold, aluminum, silver, and copper.

According to various embodiments, the bonding joint extends at least partially through the protection layer.

According to various embodiments, the bonding joint is at least partially in physical contact with the metallization layer.

According to various embodiments, a thickness of the protection layer is less than about 1 μm. According to various embodiments, a thickness of the protection layer is less than or equal to about 0.5 μm. According to various embodiments, a thickness of the protection layer is less than or equal to about 100 nm.

According to various embodiments, a thickness of the protection layer is greater than or equal to about 0.01 nm.

According to various embodiments, the nitride material is copper nitride.

According to various embodiments, the metallization layer includes or is formed from at least one of the following: a contact pad; an interlayer metallization; a redistribution layer; a seed layer.

According to various embodiments, the protection layer is at least partially exposed (in other words, uncovered).

According to various embodiments, the semiconductor device may further include: an integrated circuit component disposed at least one of in or over the substrate, wherein the metallization layer is electrically coupled with the integrated circuit component.

According to various embodiments, the semiconductor device may further include: an electrically insulating layer disposed at least one of in or over the substrate, wherein the metallization layer is disposed at least partially in the electrically insulating layer.

According to various embodiments, the semiconductor device may further include: a polymer layer disposed at least partially over the protection layer. The polymer layer may include at least one of the following: an imide, a resin, an epoxy, a mold compound.

According to various embodiments, the semiconductor device may further include: a further metallization layer (also referred as to second metallization layer) disposed at least partially over the protection layer and including at least one of: copper, aluminum, gold, silver.

According to various embodiments, a material of the further metallization layer is identical to a material of the metallization layer. In other words, the metallization layer and the further metallization layer are formed from the same material.

According to various embodiments, the semiconductor device may further include: a further metallization layer disposed at least partially between the protection layer and the metallization layer and including another material than the metallization layer. In other words, the metallization layer and the further metallization layer are formed from different materials.

According to various embodiments, the semiconductor device may include: a substrate; a metallization layer disposed at least one of in or over the substrate; a protection layer disposed at least partially over the metallization layer, wherein the metallization layer includes or is formed from copper; and wherein the protection layer includes or is formed from a nitride material including copper.

According to various embodiments, the substrate is a semiconductor substrate, e.g. the substrate may include or be formed from silicon.

According to various embodiments, the thickness of the protection layer is less than or equal to about 0.5 μm.

According to various embodiments, the metallization layer includes or is formed from at least one of the following: a contact pad; an interlayer metallization; a redistribution layer; a seed layer.

According to various embodiments, the semiconductor device may further include: a bonding joint disposed at least partially over the protection layer.

According to various embodiments, a semiconductor device may include: a substrate; a bonding pad disposed in or over the substrate; a protection layer disposed at least partially over the bonding pad; wherein the bonding pad includes or is formed from a metal and wherein the protection layer includes or is formed from a nitride of the metal.

According to various embodiments, a layer arrangement may include: a metallic surface; a protection layer including a nitride material including copper and disposed at least partially over the metallic surface; wherein a thickness of the protection layer is less than or equal to about 500 nm. According to various embodiments, the metallic surface is a copper surface.

According to various embodiments, a layer arrangement may include: a metallic surface; a protection layer including a nitride material of a metal of the metallic surface and disposed at least partially over the metallic surface; and at least one of the following disposed at least partially over the protection layer: a polymer layer, a solder joint, a bonding joint.

According to various embodiments, a method may include: providing a substrate; forming a metallization layer at least one of in or over the substrate; forming a protection layer at least partially over the metallization layer, wherein the metallization layer includes or is formed from a at least one of: copper, aluminum, gold, silver, and wherein the protection layer includes or is formed from a nitride material including at least one of: copper, aluminum, gold, silver.

According to various embodiments, a method may include: providing a metallic surface; forming a protection layer including a nitride material of a metal of the metallic surface, wherein the protection layer is formed at least partially over the metallic surface; and forming at least one of the following at least partially over the protection layer: a polymer layer, a solder joint, a bonding joint. The metallic surface may be part of a metallization layer.

According to various embodiments, the metallization layer (or the metallic surface) includes or is formed from copper; and the protection layer includes or is formed from a nitride material including copper.

According to various embodiments, a method may include: providing a substrate; forming a contact pad at least one of in or over the semiconductor substrate; forming a protection layer at least partially over the contact pad, wherein the bonding pad includes or is formed from a metal and wherein the protection layer includes or is formed from a nitride of the metal.

According to various embodiments, the method may further include removing a surface layer from the metallization layer (or the metallic surface) prior to forming the protection layer.

According to various embodiments, the method may further include forming a polymer layer at least partially over the protection layer.

According to various embodiments, forming a protection layer includes using at least one of reactive sputtering and atomic layer deposition.

According to various embodiments, the method may further include adjusting a composition of the protection layer in accordance with a predetermined conduction type.

According to various embodiments, the method may further include adjusting a spatial distribution of the composition.

According to various embodiments, adjusting the composition includes at least one of the following: heating at least a portion of the protection layer; adjusting a process parameter during forming the protection layer; exposing the protection layer to a reactant.

According to various embodiments, adjusting the composition includes adjusting a process parameter during forming the protection layer, wherein the process parameter is at least one of the following: a gas flow, a gas partial pressure, a temperature (e.g. of the semiconductor substrate); a deposition rate.

According to various embodiments, adjusting the composition includes heating at least a portion of the protection layer, wherein heating at least a portion of the protection layer includes at least one of: forming a temperature gradient in the protection layer ranging from a first temperature to a second temperature; forming a temperature distribution which is spatially substantially constant within at least a portion of the protection layer.

According to various embodiments, adjusting the composition includes heating at least a portion of the protection layer, wherein heating at least a portion of the protection layer includes using a laser source.

According to various embodiments, adjusting the composition of the protection layer includes at least one of the following: modifying a concentration of nitrogen in at least one region of the protection layer; modifying an atomic ratio of metal to nitrogen in at least one region of the protection layer; forming a composition gradient profile in at least one region of the protection layer; forming a composition being spatially substantially constant within at least one region of the protection layer;

According to various embodiments, the method may further include forming a bonding joint over the metallization layer.

According to various embodiments, forming the bonding joint includes opening the protection layer at least partially using bonding. Opening the protection layer may include applying a force to the protection layer using the bonding wire. The bonding wire may be pressed (e.g. applying the force) against the protection layer and may be moved relative to the protection layer, e.g. in an oscillating movement.

According to various embodiments, forming the metallization layer (or the metallic surface) includes at least one of the following: using a damascene process; using a double damascene process.

According to various embodiments, the method may further include: forming a further metallization (also referred to as second metallization layer) layer between the first metallization layer and the protection layer, wherein the further metallization includes a material different from a material of the metallization layer.

According to various embodiments, the method may further include: forming a further metallization layer between the substrate and the metallization layer (or the metallic surface), wherein the further metallization includes a material different from a material of the metallization layer (or the metallic surface).

According to various embodiments, the method may further include: forming a further metallization layer at least partially over the protection layer, wherein the further metallization includes or is formed from at least one of: copper, aluminum, gold, and silver.

What is claimed is:

1. A semiconductor device, comprising:
a substrate;
a metallization layer disposed at least one of in or over the substrate; and
a protection layer disposed at least partially over the metallization layer,
wherein the metallization layer comprises at least one of: copper, aluminum, gold, silver; and
wherein the protection layer comprises a nitride material comprising at least one of: copper, aluminum, gold, silver.

2. The semiconductor device of claim 1,
wherein the metallization layer comprises or is formed from copper.

3. The semiconductor device of claim 1,
wherein the protection layer comprises or is formed from a nitride material comprising copper.

4. The semiconductor device of claim 1,
wherein the protection layer comprises at least a first region and a second region which differ from each other by at least a chemical composition.

5. The semiconductor device of claim 1,
wherein a concentration of nitrogen in a first region of the protection layer is equal to or less than about 20 atomic percent and a concentration of nitrogen in a second region of the protection layer is greater than about 20 atomic percent.

6. The semiconductor device of claim 1,
wherein an electrical conductivity of a first region of the protection layer is greater than an electrical conductivity of a second region of the protection layer.

7. The semiconductor device of claim 1,
wherein the protection layer comprises a composition gradient profile ranging from a first composition to a second composition.

8. The semiconductor device of claim 1,
wherein a spatial average concentration of nitrogen within the protection layer is in the range from about 5 atomic percent to about 25 atomic percent.

9. The semiconductor device of claim 1, further comprising:
a solder joint disposed at least partially over the protection layer.

10. The semiconductor device of claim 1, further comprising:
a bonding joint disposed at least partially over the protection layer.

11. The semiconductor device of claim 10,
wherein the bonding joint extends at least partially through the protection layer.

12. The semiconductor device of claim 1,
wherein a thickness of the protection layer is less than about 1 μm.

13. The semiconductor device of claim 1,
wherein the metallization layer comprises at least one of the following:
a contact pad;
an interlayer metallization;
a redistribution layer;
a seed layer.

14. The semiconductor device of claim 1, further comprising:
an electrically insulating layer disposed at least one of in or over the substrate, wherein
the metallization layer is disposed at least partially in the electrically insulating layer.

15. The semiconductor device of claim 1, further comprising:
a polymer layer disposed at least partially over the protection layer.

16. The semiconductor device of claim 1, further comprising:
a further metallization layer disposed at least partially over the protection layer and comprising at least one of: copper, aluminum, gold, silver.

17. The semiconductor device of claim 16,
wherein a material of the further metallization layer is identical to a material of the metallization layer.

18. The semiconductor device of claim 1, further comprising:
a further metallization layer disposed at least partially between the protection layer and the metallization layer and comprising another material than the metallization layer.

19. A semiconductor device, comprising:
a substrate;
a metallization layer disposed at least one of in or over the substrate; and
a protection layer disposed at least partially over the metallization layer,
wherein the metallization layer comprises copper; and
wherein the protection layer comprises a nitride material comprising copper.

20. The semiconductor device of claim 19,
wherein the thickness of the protection layer is less than or equal to about 0.5 μm.

21. The semiconductor device of claim 19,
wherein the metallization layer comprises at least one of the following:
a contact pad;
an interlayer metallization;
a redistribution layer;
a seed layer.

22. The semiconductor device of claim 19, further comprising:
a bonding joint disposed at least partially over the protection layer.

23. A semiconductor device, comprising:
a substrate;
a bonding pad disposed in or over the substrate; and
a protection layer disposed at least partially over the bonding pad;
wherein the bonding pad comprises a metal and wherein the protection layer comprises a nitride of the metal.

24. A layer arrangement, comprising:
a metallic surface; and
a protection layer comprising a nitride material comprising copper and disposed at least partially over the metallic surface;
wherein a thickness of the protection layer is less than or equal to about 500 nm.
